(19) United States
(12) Patent Application Publication
(10) Pub. No.: US 2024/0186760 A1
(43) Pub. Date: Jun. 6, 2024

(54) LASER APPARATUS AND ELECTRONIC DEVICE MANUFACTURING METHOD

(71) Applicant: Gigaphoton Inc., Tochigi (JP)

(72) Inventors: Takayuki YABU, Oyama-shi (JP); Taisuke MIURA, Oyama-shi (JP)

(73) Assignee: Gigaphoton Inc., Tochigi (JP)

(21) Appl. No.: 18/402,829

(22) Filed: Jan. 3, 2024

Related U.S. Application Data
(63) Continuation of application No. PCT/JP2021/029287, filed on Aug. 6, 2021.

(51) Int. Cl. H01S 3/10; G02F 1/35; G03F 7/00; H01S 3/094; H01S 3/102; H01S 3/108; H01S 3/16

(52) U.S. Cl. CPC H01S 3/10092; G02F 1/3507; G03F 7/70025; G03F 7/70191; G03F 7/70525; H01S 3/094076; H01S 3/1024; H01S 3/108; H01S 3/1625; H01S 3/1636; G02F 1/3534

(57) ABSTRACT

A laser apparatus includes a first seed laser outputting continuous-wave first seed laser light having a first wavelength, a second seed laser outputting continuous-wave second seed laser light having a second wavelength, an optical switch sequentially selecting the first seed laser light and the second seed laser light one at a time and outputting the selected seed laser light, a first pulsing section pulsing the selected laser light and outputting first pulse laser light, a wavelength converter outputting output laser light by using the first pulse laser light, and a processor controlling a timing of sequentially selecting the first seed laser light and the second seed laser light one at a time. The wavelength converter outputs the output laser light having a first converted wavelength produced using the first wavelength, and outputs the output laser light having a second converted wavelength produced using the second wavelength.

### CROSS-REFERENCE TO RELATED APPLICATIONS

The present application is a continuation application of International Application No. PCT/JP2021/029287, filed on Aug. 6, 2021, the entire contents of which are hereby incorporated by reference.

### BACKGROUND

### 1. Technical Field

The present disclosure relates to a laser apparatus and an electronic device manufacturing method.

### 2. Related Art

In recent years, a semiconductor exposure apparatus is required to improve the resolution thereof as semiconductor integrated circuits are increasingly miniaturized and highly integrated. To this end, reduction in the wavelength of light emitted from a light source for exposure is underway. For example, a KrF excimer laser apparatus, which outputs laser light having a wavelength of about 248 nm, and an ArF excimer laser apparatus, which outputs laser light having a wavelength of about 193 nm, are used as a gas laser apparatus for exposure.

The light from spontaneously oscillating KrF and ArF excimer laser apparatuses has a wide spectral linewidth ranging from 350 to 400 pm. A projection lens made of a material that transmits ultraviolet light, such as KrF and ArF laser light, therefore produces chromatic aberrations in some cases. As a result, the resolution of the projection lens may decrease. To avoid the decrease in the resolution, the spectral linewidth of the laser light output from the gas laser apparatus needs to be narrow enough to make the chromatic aberrations negligible. To this end, a line narrowing module (LNM) including a line narrowing element (etalon or grating) is provided in some cases in a laser resonator of the gas laser apparatus to narrow the spectral linewidth. A gas laser apparatus providing a narrowed spectral linewidth is hereinafter referred to as a narrowed-line laser apparatus.

### CITATION LIST

### Patent Literature

[PTL 1] U.S. Patent application Publication No. 2013/0215916

[PTL 2] WO2017/046860

[PTL 3] U.S. Patent application Publication No. 2019/0245321

[PTL 4] WO2021/015919

### SUMMARY

In an aspect of the present disclosure, a laser apparatus includes a first seed laser configured to output continuous-wave first seed laser light having a first oscillation wavelength, a second seed laser configured to output continuous-wave second seed laser light having a second oscillation wavelength, an optical switch configured to sequentially select the first seed laser light and the second seed laser light one at a time and outputs the selected seed laser light as selected laser light, a first pulsing section configured to pulse the selected laser light and output first pulse laser light, a wavelength converter configured to output output laser light by using the first pulse laser light, the wavelength converter outputting the output laser light having a first converted wavelength produced by wavelength conversion using the first oscillation wavelength, the wavelength converter outputting the output laser light having a second converted wavelength produced by wavelength conversion using the second oscillation wavelength, and a processor configured to control a timing at which the optical switch sequentially selects the first seed laser light and the second seed laser light one at a time.

In another aspect of the present disclosure, a laser apparatus includes a first seed laser configured to output continuous-wave first seed laser light having a first oscillation wavelength, a second seed laser configured to output continuous-wave second seed laser light having a second oscillation wavelength, a first pulsing section configured to pulse the first seed laser light and output first pulse laser light, a third pulsing section configured to pulse the second seed laser light and output third pulse laser light, an optical switch configured to sequentially select the first pulse laser light and the third pulse laser light one at a time and output the selected pulse laser light as selected laser light, a wavelength converter configured to output output laser light by using the selected laser light, the wavelength converter outputting the output laser light having a first converted wavelength produced by wavelength conversion using the first oscillation wavelength, the wavelength converter outputting the output laser light having a second converted wavelength produced by wavelength conversion using the second oscillation wavelength, and a processor configured to control a timing at which the optical switch sequentially selects the first pulse laser light and the third pulse laser light one at a time.

An electronic device manufacturing method according to an aspect of the present disclosure includes generating output laser light by using a laser apparatus, outputting the output laser light to an exposure apparatus, and exposing a photosensitive substrate to the output laser light in the exposure apparatus to manufacture electronic devices, the laser apparatus including a first seed laser configured to output continuous-wave first seed laser light having a first oscillation wavelength, a second seed laser configured to output continuous-wave second seed laser light having a second oscillation wavelength, an optical switch configured to sequentially select the first seed laser light and the second seed laser light one at a time and output the selected seed laser light as selected laser light, a first pulsing section configured to pulse the selected laser light and output first pulse laser light, a wavelength converter configured to output the output laser light by using the first pulse laser light, the wavelength converter outputting the output laser light having a first converted wavelength produced by wavelength conversion using the first oscillation wavelength, the wavelength converter outputting the output laser light having a second converted wavelength produced by wavelength conversion using the second oscillation wavelength, and a processor configured to control a timing at which the optical switch sequentially selects the first seed laser light and the second seed laser light one at a time.

An electronic device manufacturing method according to another aspect of the present disclosure includes generating output laser light by using a laser apparatus, outputting the output laser light to an exposure apparatus, and exposing a photosensitive substrate to the output laser light in the exposure apparatus to manufacture electronic devices, the laser apparatus including a first seed laser configured to output continuous-wave first seed laser light having a first oscillation wavelength, a second seed laser configured to output continuous-wave second seed laser light having a second oscillation wavelength, a first pulsing section configured to pulse the first seed laser light and output first pulse laser light, a third pulsing section configured to pulse the second seed laser light and output third pulse laser light, an optical switch configured to sequentially select the first pulse laser light and the third pulse laser light one at a time and output the selected pulse laser light as selected laser light, a wavelength converter configured to output the output laser light by using the selected laser light, the wavelength converter outputting the output laser light having a first converted wavelength produced by wavelength conversion using the first oscillation wavelength, the wavelength converter outputting the output laser light having a second converted wavelength produced by wavelength conversion using the second oscillation wavelength, and a processor configured to control a timing at which the optical switch sequentially selects the first pulse laser light and the third pulse laser light one at a time.

### BRIEF DESCRIPTION OF THE DRAWINGS

Embodiments of the present disclosure will be described below only by way of example with reference to the accompanying drawings.

FIG. 1 schematically shows the configuration of an exposure system according to Comparative Example.

FIG. 2 schematically shows the configuration of a laser apparatus according to Comparative Example.

FIG. 3 schematically shows the configuration of a laser apparatus according to a first embodiment.

FIG. 4 is a timing chart in accordance with which the laser apparatus according to the first embodiment operates.

FIG. 5 is a flowchart showing the procedure of processes carried out by a laser control processor in the first embodiment.

FIG. 6 is a timing chart in accordance with which the laser apparatus according to a first variation of the first embodiment operates.

FIG. 7 is a flowchart showing the procedure of processes carried out by the laser control processor in the first variation.

FIG. 8 is a timing chart in accordance with which the laser apparatus according to a second variation of the first embodiment operates.

FIG. 9 is a flowchart showing the procedure of processes carried out by the laser control processor in the second variation.

FIG. 10 is a timing chart in accordance with which the laser apparatus according to a third variation of the first embodiment operates.

FIG. 11 is a flowchart showing the procedure of processes carried out by the laser control processor in the third variation.

FIG. 12 schematically shows the configuration of a laser apparatus according to a second embodiment.

FIG. 13 is a timing chart in accordance with which the laser apparatus according to the second embodiment operates.

FIG. 14 is a flowchart showing the procedure of processes carried out by the laser control processor in the second embodiment.

FIG. 15 schematically shows the configuration of a laser apparatus according to a third embodiment.

FIG. 16 schematically shows the configuration of a wavelength converter according to a first variation of the third embodiment.

FIG. 17 schematically shows the configuration of a laser apparatus according to a second variation of the third embodiment.

FIG. 18 schematically shows the configuration of a laser apparatus according to a fourth embodiment.

FIG. 19 schematically shows the configuration of a wavelength converter according to a first variation of the fourth embodiment.

FIG. 20 schematically shows the configuration of a laser apparatus according to a fifth embodiment.

FIG. 21 schematically shows the configuration of a laser apparatus according to a sixth embodiment.

FIG. 22 shows a power oscillator shown in FIG. 21 viewed in a direction different from that in FIG. 21.

### DETAILED DESCRIPTION

### Contents

1. Comparative Example
1.1 Exposure system
1.1.1 Configuration
1.1.2 Operation
1.2 Laser apparatus
1.2.1 Configuration
1.2.2 Operation
1.3 Problems with Comparative Example
2. Laser apparatus that converts first seed laser light and second seed laser light in terms of wavelength to oscillate at two wavelengths
2.1 Configuration
2.2 Operation
2.3 Process procedure
2.4 Effects
3. Laser apparatus that switches wavelength in the middle of pulse
3.1 Operation
3.2 Effects
4. Laser apparatus capable of adjusting ratio between light intensities of wavelength components
4.1 Operation
4.2 Effects
5. Laser apparatus that adjusts pulse energy of pumping laser light
5.1 Operation
5.2 Effects
6. Laser apparatus that includes third seed laser and oscillates at plurality of wavelengths
6.1 Configuration
6.2 Operation
6.3 Process procedure
6.4 Effects
7. Laser apparatus that performs wavelength conversion through sum-frequency mixing
7.1 Configuration
7.2 Operation
7.3 Effects
8. Laser apparatus that changes posture of nonlinear optical crystal in synchronization with wavelength switching
8.1 Configuration and operation
8.2 Effects
9. Laser apparatus with first and third pulsing sections disposed upstream from optical switch
9.1 Configuration and operation
9.2 Effects
10. Laser apparatus that pulses selected laser light with optical parametric amplifier
10.1 Configuration and operation
10.2 Effects
11. Laser apparatus that changes posture of nonlinear optical crystal in synchronization with wavelength switching
12. Laser apparatus including amplifier
12.1 Configuration
12.2 Operation
13. Laser apparatus including ring resonator
13.1 Configuration
13.2 Operation
14. Others

Embodiments of the present disclosure will be described below in detail with reference to the drawings. The embodiments described below show some examples of the present disclosure and are not intended to limit the contents of the present disclosure. Furthermore, all configurations and operations described in the embodiments are not necessarily essential as configurations and operations in the present disclosure. The same component has the same reference character, and no redundant description of the same component will be made.

### 1. Comparative Example

### 1.1 Exposure System

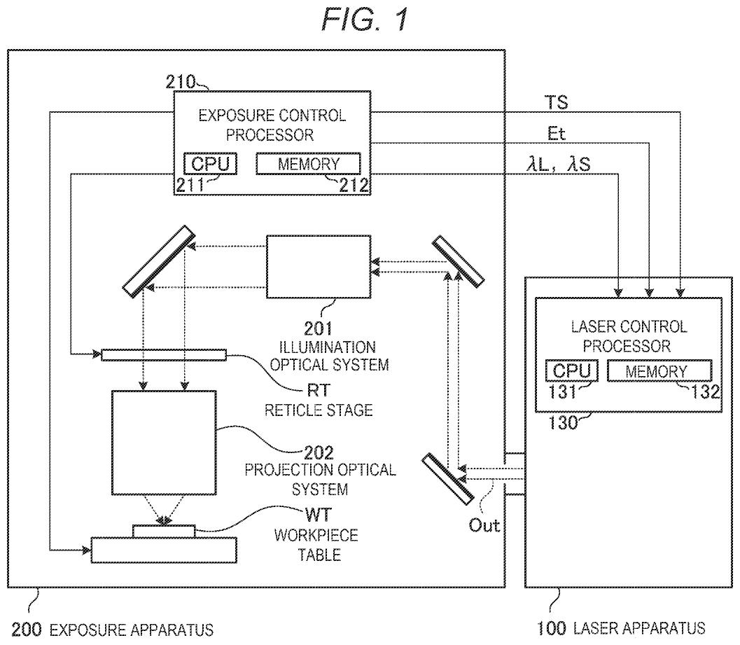

FIG. 1 schematically shows the configuration of an exposure system according to Comparative Example. Comparative Example in the present disclosure is an aspect that the applicant is aware of as known only by the applicant, and is not a publicly known example that the applicant is self-aware of.

An exposure system includes a laser apparatus 100 and an exposure apparatus 200. FIG. 1 shows the laser apparatus 100 in a simplified form.

The laser apparatus 100 includes a laser control processor 130. The laser control processor 130 is a processing apparatus including a memory 132, which stores a control program, and a CPU (central processing unit) 131, which executes the control program. The laser control processor 130 is specially configured or programmed to perform a variety of processes contained in the present disclosure. The laser control processor 130 corresponds to the processor in the present disclosure. The laser apparatus 100 is configured to output output laser light Out toward the exposure apparatus 200.

### 1.1.1 Configuration

The exposure apparatus 200 includes an illumination optical system 201, a projection optical system 202, and an exposure control processor 210, as shown in FIG. 1.

The illumination optical system 201 illuminates a reticle pattern of a reticle that is not shown but is placed on a reticle stage RT with the output laser light Out having entered the exposure apparatus 200 from the laser apparatus 100.

The projection optical system 202 performs reduction projection on the output laser light Out having passed through the reticle to bring the output laser light Out into focus on a workpiece that is not shown but is placed on a workpiece table WT. The workpiece is a photosensitive substrate, such as a semiconductor wafer onto which a photoresist has been applied in the form of a film.

The exposure control processor 210 is a processing apparatus including a memory 212, which stores a control program, and a CPU 211, which executes the control program. The exposure control processor 210 is specially configured or programmed to carry out a variety of processes contained in the present disclosure. The exposure control processor 210 oversees the control of the exposure apparatus 200.

### 1.1.2 Operation

The exposure control processor 210 transmits a variety of parameters including target wavelengths λL and λS and target pulse energy Et, and a trigger signal TS to the laser control processor 130. The laser control processor 130 controls the laser apparatus 100 in accordance with the parameters and the signal.

The exposure control processor 210 translates the reticle stage RT and the workpiece table WT in opposite directions in synchronization with each other. The workpiece is thus exposed to the output laser light Out having reflected the reticle pattern.

The exposure step described above causes the reticle pattern to be transferred to the semiconductor wafer. The following multiple steps allow manufacture of electronic devices.

### 1.2 Laser Apparatus

### 1.2.1 Configuration

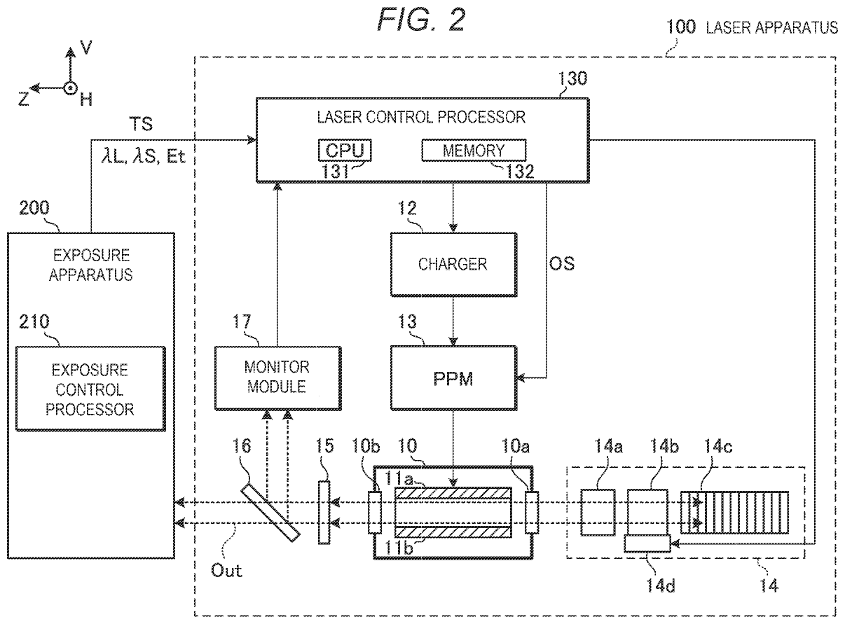

FIG. 2 schematically shows the configuration of the laser apparatus 100 according to Comparative Example. FIG. 2 shows the exposure apparatus 200 in a simplified form.

The laser apparatus 100 includes a laser chamber 10, a charger 12, a pulse power module (PPM) 13, a line narrowing module 14, an output coupling mirror 15, and a monitor module 17 as well as the laser control processor 130. The line narrowing module 14 and the output coupling mirror 15 constitute an optical resonator.

The laser chamber 10 is disposed in the optical path of the optical resonator. The laser chamber 10 is provided with windows 10a and 10b.

The laser chamber 10 accommodates a pair of discharge electrodes 11a and 11b. The laser chamber 10 is filled with a laser gas containing, for example, an argon or krypton gas as a rare gas, a fluorine gas as a halogen gas, and a neon gas as a buffer gas.

The charger 12 retains electrical energy to be supplied to the pulse power module 13. The pulse power module 13 includes a charging capacitor and a switch none of which is shown. The charger 12 is connected to the charging capacitor. The charging capacitor is connected to the discharge electrode 11a. The discharge electrode 11b is connected to the ground potential.

The line narrowing module 14 includes a plurality of prisms 14a and 14b and a grating 14c.

The prisms 14a and 14b are disposed in this order in the optical path of the light beam having exited via the window 10a. A rotary stage 14d allows the prism 14b to rotate around an axis parallel to an axis V.

The grating 14c is disposed in the optical path of the light beam having passed through the prisms 14a and 14b. The direction of the grooves of the grating 14c is parallel to the axis V.

The output coupling mirror 15 includes a partially reflective mirror.

A beam splitter 16 is disposed in the optical path of the output laser light Out output via the output coupling mirror 15, transmits part of the output laser light Out at high transmittance, and reflects another part of the output laser light Out. The monitor module 17 is disposed in the optical path of the output laser light Out reflected off the beam splitter 16.

### 1.2.2 Operation

The laser control processor 130 acquires the variety of parameters including the target wavelengths λL and λS and the target pulse energy Et, and receives the trigger signal TS from the exposure control processor 210. The laser control processor 130 transmits an oscillation trigger signal OS based on the trigger signal TS to the pulse power module 13. The switch provided in the pulse power module 13 is turned on when the switch receives the oscillation trigger signal OS from the laser control processor 130. When the switch is turned on, the pulse power module 13 generates a pulse-shaped high voltage from the electric energy charged in the charger 12, and applies the high voltage to the discharge electrode 11a.

When the high voltage is applied to the discharge electrode 11a, discharge occurs in the discharge space between the discharge electrodes 11a and 11b. The energy of the discharge excites the laser gas in the laser chamber 10, and the excited laser gas transitions to a high energy level. Thereafter, when the excited laser gas transitions to a low energy level, the laser gas emits light having a wavelength according to the difference between the energy levels.

The light generated in the laser chamber 10 exits as a light beam out of the laser chamber 10 via the windows 10a and 10b. The beam width of the light beam having exited via the window 10a is enlarged by each of the prisms 14a and 14b in a plane parallel to a plane HZ, which is a plane perpendicular to the axis V. The light beam having passed through the prisms 14a and 14b is incident on the grating 14c.

The light beam incident on the grating 14c is reflected off and diffracted by a plurality of grooves of the grating 14c in the direction according to the wavelength of the light. The grating 14c is disposed in the Littrow arrangement, which causes the angle of incidence of the light beam incident from the prism 14b on the grating 14c to be equal to the angle of diffraction of the diffracted light having a desired wavelength.

The prisms 14a and 14b reduce the beam width of the light having returned from the grating 14c in the plane parallel to the plane HZ, and cause the resultant light beam to return into the laser chamber 10 via the window 10a.

The output coupling mirror 15 transmits part of the light beam having exited via the window 10b and reflects another part of the light beam back into the laser chamber 10.

The light beam having exited out of the laser chamber 10 thus travels back and forth between the line narrowing module 14 and the output coupling mirror 15. The light beam is amplified whenever passing through the discharge space in the laser chamber 10. The light beam undergoes the line narrowing operation whenever deflected back by the line narrowing module 14. The light beam thus having undergone the laser oscillation and the line narrowing operation is output as the output laser light Out via the output coupling mirror 15.

The monitor module 17 measures the pulse energy and the wavelength of the output laser light Out, and transmits the measured pulse energy and wavelength to the laser control processor 130.

The output laser light Out having passed through the beam splitter 16 enters the exposure apparatus 200.

The laser control processor 130 controls a charging voltage to be applied to the charger 12 based on the target pulse energy Et received from the exposure control processor 210. The control of the charging voltage includes feedback control based on the pulse energy measured by the monitor module 17.

The laser control processor 130 controls the rotary stage 14d via a driver that is not shown based on the target wavelengths λL and λS received from the exposure control processor 210. The posture of the prism 14b changes in accordance with the angle of rotation of the rotary stage 14d. The angle of incidence of the light beam incident on the grating 14c thus changes, and the wavelength selected by the line narrowing module 14 changes accordingly. The control of the rotary stage 14d includes feedback control based on the wavelength measured by the monitor module 17. Switching the target wavelengths λL and λS from one to the other for each set of a plurality of pulses changes the wavelength of the output laser light Out periodically for each set of the plurality of pulses. The laser apparatus 100 can thus oscillate at the two wavelengths. The laser apparatus 100 can instead perform multi-wavelength oscillation by changing the wavelength of the output laser light Out stepwise between the target wavelengths λL and λS.

The focal length in the exposure apparatus 200 depends on the wavelength of the output laser light Out. The output laser light Out having oscillated at the two wavelengths or a plurality of wavelengths and entered the exposure apparatus 200 can form images at a plurality of different positions in the direction of the optical path axis of the output laser light Out, so that the depth of focus practically increases. For example, even when a photoresist film having a large thickness is exposed to the output laser light Out, the image formation performance can be maintained in the thickness direction of the photoresist film.

1.3 Problems with Comparative Example

To switch the wavelength of the output laser light Out by controlling the rotary stage 14d as in Comparative Example, it is necessary to increase the rotational speed of the rotary stage 14d in accordance with the repetition frequency of the output laser light Out. That is, after one pulse of the output laser light Out having the target wavelength λL is output, an attempt to output the next pulse having the target wavelength λS fails unless the rotary stage 14d rotates in time. If the wavelength of the output laser light Out cannot be accurately controlled, the exposure performance may deteriorate.

### 2. Laser Apparatus That Converts First Seed Laser Light and Second Seed Laser Light in Terms of Wavelength to Oscillate at Two Wavelengths

### 2.1 Configuration

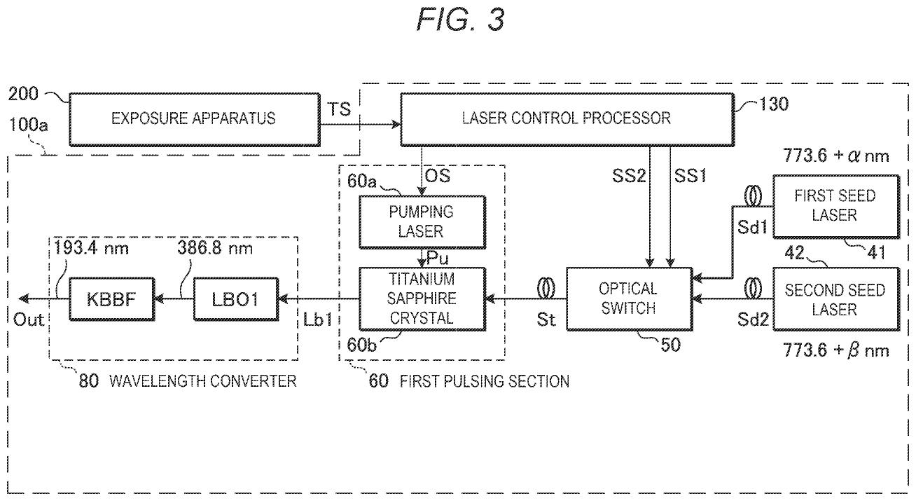

FIG. 3 schematically shows the configuration of a laser apparatus 100a according to a first embodiment. The laser apparatus 100a includes the laser control processor 130, a first seed laser 41, a second seed laser 42, an optical switch 50, a first pulsing section 60, and a wavelength converter 80.

The configurations of the laser control processor 130 and the exposure apparatus 200 are the same as the corresponding configurations in Comparative Example. The laser control processor 130 receives the same variety of parameters and trigger signal TS as those in Comparative Example from the exposure apparatus 200.

The first seed laser 41 and the second seed laser 42 each include a solid-state laser, such as a semiconductor laser. The first seed laser 41 is configured to output continuous-wave first seed laser light Sd1 having a first oscillation wavelength λ1. The second seed laser 42 is configured to output continuous-wave second seed laser light Sd2 having a second oscillation wavelength λ2. The wavelengths λ1 and λ2 are slightly differ from each other; the wavelength λ1 is, for example, 773.600+α nm and the wavelength λ2 is, for example, 773.600+βnm. The wavelengths λ1 and λ2 are each longer than or equal to 700 nm but shorter than or equal to 800 nm, and the difference between the wavelengths λ1 and λ2 may be greater than or equal to 1 μm but smaller than or equal to 110 pm. The constant α may be 0.000 nm, and the constant β may be 0.004 nm.

The optical switch 50 is configured to sequentially select the first seed laser light Sd1 and the second seed laser light Sd2 one at a time and output the selected seed laser light as selected laser light St. The optical switch 50 selects the first seed laser light Sd1 when a first selection signal SS1 received from the laser control processor 130 is ON, and selects the second seed laser light Sd2 when a second selection signal SS2 received from the laser control processor 130 is ON. As described above, the timing at which the optical switch 50 sequentially selects the first seed laser light Sd1 and the second seed laser light Sd2 one at a time is controlled by the laser control processor 130.

The optical switch 50 may be a switch using a mechanical optical path switching mechanism, a switch using an electro-optic effect, a switch using a thermo-optic effect, or a switch using a semiconductor optical waveguide. The mechanical optical path switching mechanism may include a micro-electro mechanical system (MEMS). The selected laser light St selected by the optical switch 50 from the first seed laser light Sd1 and the second seed laser light Sd2 enters the first pulsing section 60. The laser light that has not been selected may enter a laser damper that is not shown.

The first pulsing section 60 includes a pumping laser 60a and a titanium sapphire crystal 60b. The pumping laser 60a includes, for example, an yttrium lithium fluoride (YLF) laser, and is configured to output pulse-shaped pumping laser light Pu when receiving the oscillation trigger signal OS from the laser control processor 130. The titanium sapphire crystal 60b is a laser crystal disposed in the optical path of the selected laser light St. The titanium sapphire crystal 60b is configured to amplify and pulse the selected laser light St when excited by the pumping laser light Pu. The first pulsing section 60 thus pulses the selected laser light St and outputs first pulse laser light Lb1. The selected laser light St incident on the titanium sapphire crystal 60b that is not excited by the pumping laser light Pu may then enter the laser damper, which is not shown.

The wavelength of the first pulse laser light Lb1 is equal to the wavelength of the selected laser light St at the pulsing timing. For example, the wavelength of each pulse from one of the seed lasers is 773.600+α nm, and the wavelength of each pulse from the other one of the seed lasers is 773.600+β nm. The pulse temporal width of the first pulse laser light Lb1 is equal to the pulse temporal width of the pumping laser light Pu, for example, longer than or equal to 10 ns but shorter than or equal to 40 ns.

The wavelength converter 80 includes a nonlinear optical crystal that performs wavelength conversion using the first pulse laser light Lb1 and outputs the output laser light Out. The nonlinear optical crystal includes, for example, a crystal LBO1 made of lithium triborate (LBO) and a crystal KBBF made of potassium beryllium fluoroborate (KBBF).

When the wavelength λ1 of the first seed laser light Sd1 is set at 773.600 nm, the crystal LBO1 converts the light having the wavelength of 773.600 nm into light having a wavelength of 386.800 nm, which is the second harmonic of the light before the conversion. The crystal KBBF converts the light having the wavelength of 386.800 nm into the output laser light Out having a wavelength of 193.400 nm, which is the second harmonic of the light before the conversion.

When the wavelength λ2 of the second seed laser light Sd2 is set at 773.604 nm, the crystals LBO1 and KBBF convert the light having the wavelength of 773.604 nm into the output laser light Out having a wavelength of 193.401 nm. The wavelength as a result of the wavelength conversion of the wavelength λ2 is not shown.

The wavelength of 193.400 nm is an example of the first converted wavelength in the present disclosure, and the wavelength of 193.401 nm is an example of the second converted wavelength in the present disclosure.

The wavelength converter 80 thus outputs the output laser light Out having the first converted wavelength through the wavelength conversion using the near-infrared wavelength λ1, and outputs the output laser light Out having the second converted wavelength through the wavelength conversion using the near-infrared wavelength λ2. The first and second converted wavelengths are approximately equal to the wavelength of the light output from an ArF excimer laser apparatus.

### 2.2 Operation

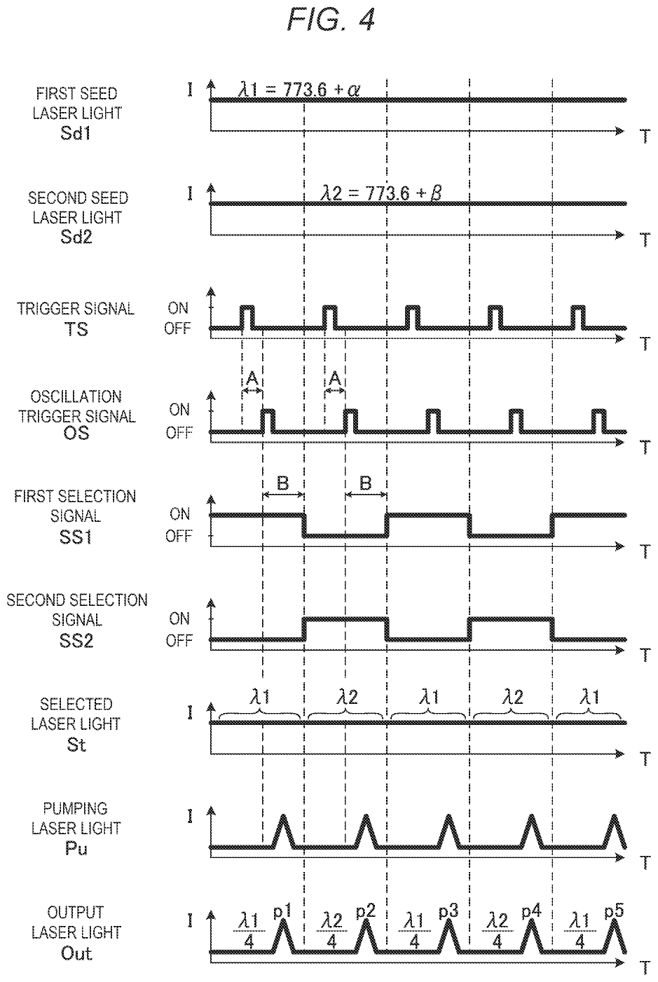

FIG. 4 is a timing chart in accordance with which the laser apparatus 100a according to the first embodiment operates. The horizontal axis represents time T, and the vertical broken lines each indicate that events connected to each other by the broken line occur approximately at the same time. The vertical axis of each of the first seed laser light Sd1, and the second seed laser light Sd2, the selected laser light St, the pumping laser light Pu, and the output laser light Out indicates light intensity I. The vertical axis of each of the trigger signal TS, the oscillation trigger signal OS, the first selection signal SS1, and the second selection signal SS2 represents signal intensity, and each signal intensity can have one of two values, ON and OFF.

The first seed laser light Sd1 and the second seed laser light Sd2 are each continuous-wave laser light and have the same light intensity I but different wavelengths λ1 and λ2.

The trigger signal TS received from the exposure apparatus 200 as an external apparatus is a pulse-shaped signal that is turned on at approximately fixed time intervals.

The oscillation trigger signal OS is generated after a period A from the timing of the reception of the trigger signal TS, and is transmitted to the pumping laser 60a of the first pulsing section 60.

The first selection signal SS1 and the second selection signal SS2 are signals so alternately become ON and OFF that one of the signals is ON and the other is OFF. After a period B from the timing of the transmission of the oscillation trigger signal OS, the first selection signal SS1 and the second selection signal SS2 are switched from ON to OFF and vice versa and transmitted to the optical switch 50.

As described above, the first pulsing section 60 and the optical switch 50 are controlled with respect to the timing of the reception of the trigger signal TS.

The selected laser light St is laser light having substantially fixed light intensity I, and has the wavelength λ1 during the period for which the first selection signal SS1 is ON and the wavelength λ2 during the period for which the second selection signal SS2 is ON.

The pumping laser light Pu is pulse-shaped laser light generated whenever the pumping laser 60a receives the oscillation trigger signal OS. The timing of the generation of the pumping laser light Pu is controlled by the period A.

The first pulse laser light Lb1 is generated when the pumping laser light Pu enters the titanium sapphire crystal 60b. The wavelength of the selected laser light St is switched after the generation of one pulse contained in the first pulse laser light Lb1 is completed but before the generation of the next pulse starts. The timing of the switching of the wavelength of the selected laser light St is controlled by the period B.

The output laser light Out is pulse-shaped laser light generated when the first pulse laser light Lb1 enters the wavelength converter 80. Pulses p1, p3, and p5 contained in the output laser light Out are generated during a period for which the wavelength of the selected laser light St is λ1, and have a wavelength of (λ1)/4. Pulses p2 and p4 contained in the output laser light Out are generated during a period for which the wavelength of the selected laser light St is λ2, and have a wavelength of (λ2)/4.

The wavelength (λ1)/4 is an example of the first converted wavelength in the present disclosure, and the wavelength (λ2)/4 is an example of the second converted wavelength in the present disclosure.

The present disclosure has been described with reference to the case where the first selection signal SS1 and the second selection signal SS2 are each so switched from ON to OFF and vice versa that the wavelength of the output laser light Out is switched on a pulse basis, but not necessarily. The frequency at which the first selection signal SS1 and the second selection signal SS2 are switched between ON and OFF may be so set that the wavelength of Na consecutive pulses contained in the output laser light Out is the first converted wavelength, and that the wavelength of the next Nb consecutive pulses contained in the output laser light Out is the second converted wavelength. Na and Nb are natural numbers and may be equal to each other or differ from each other. The ratio between the accumulated energy of the output laser light Out having the first converted wavelength and the accumulated energy of the output laser light Out having the second converted wavelength in a certain period may be adjusted by the ratio between Na and Nb.

### 2.3 Process Procedure

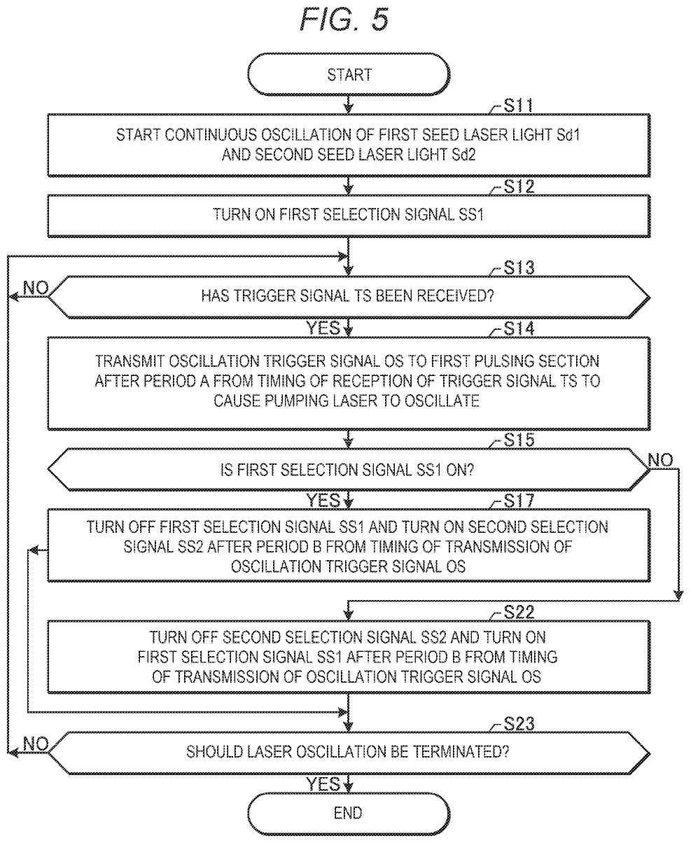

FIG. 5 is a flowchart showing the procedure of processes carried out by the laser control processor 130 in the first embodiment.

In S11, the laser control processor 130 starts continuous oscillation of the first seed laser light Sd1 and the second seed laser light Sd2.

In S12, the laser control processor 130 turns on the first selection signal SS1.

In S13, the laser control processor 130 evaluates whether it has received the trigger signal TS. When the laser control processor 130 has not received the trigger signal TS (NO in S13), the laser control processor 130 waits until it receives the trigger signal TS. When the laser control processor 130 has received the trigger signal TS (YES in S13), the laser control processor 130 proceeds to the process in S14.

In S14, the laser control processor 130 transmits the oscillation trigger signal OS to the first pulsing section 60 after the period A from the timing of the reception of the trigger signal TS to cause the pumping laser 60a to oscillate.

In S15, the laser control processor 130 evaluates whether the first selection signal SS1 is ON. When the first selection signal SS1 is ON (YES in S15), the laser control processor 130 proceeds to the process in S17. When the first selection signal SS1 is OFF (NO in S15), the laser control processor 130 proceeds to the process in S22.

In S17, the laser control processor 130 turns off the first selection signal SS1 and turns on the second selection signal SS2 after the period B from the timing of the transmission of the oscillation trigger signal OS. After S17, the laser control processor 130 proceeds to the process in S23.

In S22, the laser control processor 130 turns off the second selection signal SS2 and turns on the first selection signal SS1 after the period B from the timing of the transmission of the oscillation trigger signal OS. After S22, the laser control processor 130 proceeds to the process in S23.

In step S23, the laser control processor 130 evaluates whether the laser oscillation should be terminated. When the laser oscillation should not be terminated (NO in S23), the laser control processor 130 returns to the process in S13. When the laser oscillation should be terminated (YES in S23), the laser control processor 130 terminates the processes in the present flowchart.

### 2.4 Effects

According to the first embodiment, the first seed laser light Sd1 and the second seed laser light Sd2 are sequentially selected one at a time by the optical switch 50, pulsed, and then converted in terms of wavelength. The configuration described above, in which the optical switch 50 can operate at high speed, allows high-speed switching between the first and second converted wavelengths contained in the output laser light Out. Furthermore, since the first seed laser light Sd1 and the second seed laser light Sd2 are continuous-wave laser light and have stable energy, it can be expected that the pulse energy of the output laser light Out is also stable.

According to the first embodiment, the optical switch 50 and the first pulsing section 60 are controlled with respect to the timing of the reception of the trigger signal TS. The configuration described above allows the operation of the optical switch 50 to be precisely synchronized with the operation of the first pulsing section 60.

### 3. Laser Apparatus That Switches Wavelength in the Middle of Pulse

### 3.1 Operation

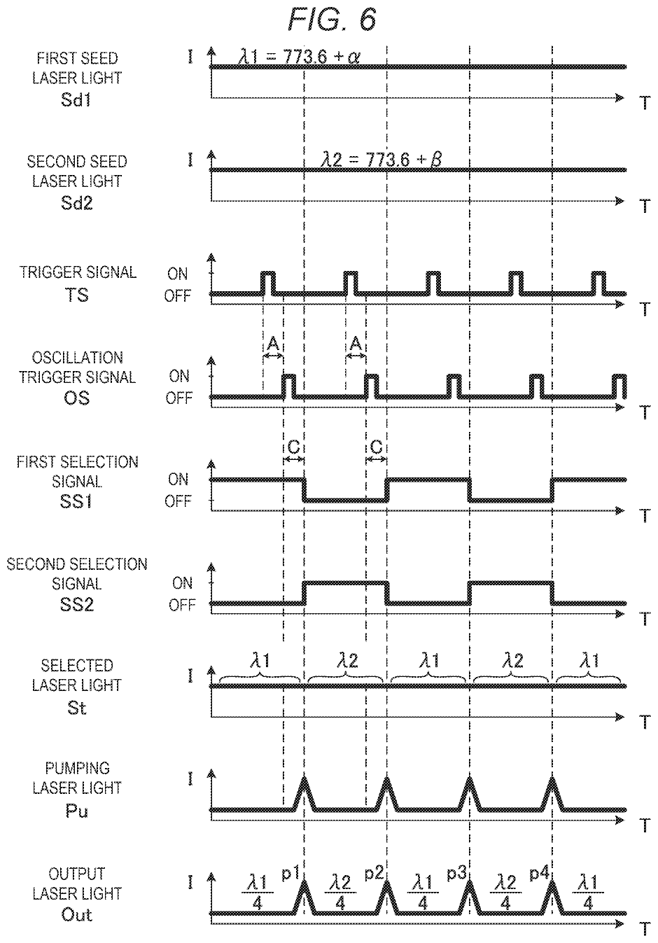

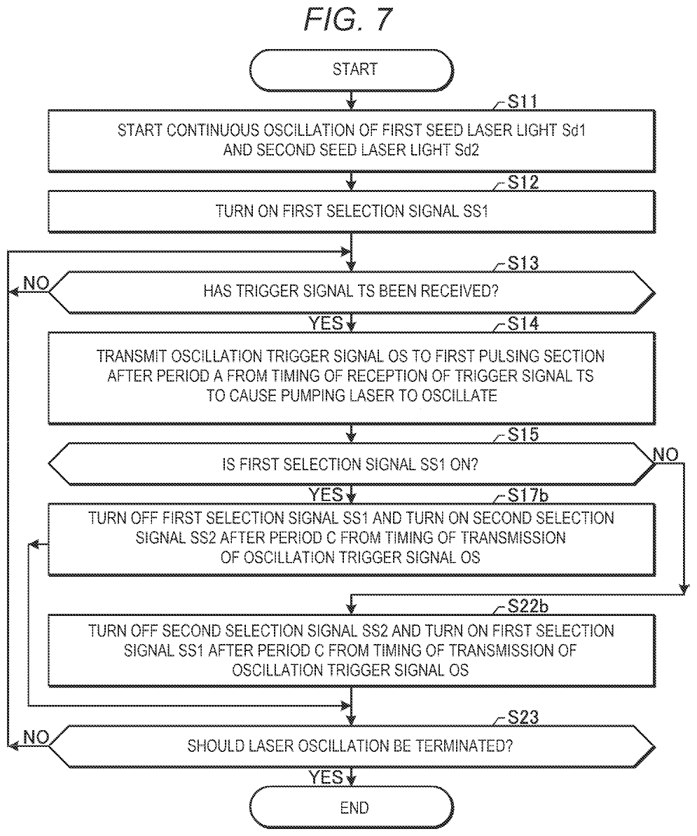

FIG. 6 is a timing chart in accordance with which the laser apparatus 100a according to a first variation of the first embodiment operates. FIG. 7 is a flowchart showing the procedure of processes carried out by the laser control processor 130 in the first variation. The configuration of the first variation is the same as the configuration shown in FIG. 3.

The first variation differs from the example shown in FIGS. 3 to 5 in terms of the timings when the first selection signal SS1 and the second selection signal SS2 are switched from ON to OFF and vice versa.

The first selection signal SS1 and the second selection signal SS2 are switched from ON to OFF and vice versa after a period C from the timing of the transmission of the oscillation trigger signal OS, as shown in S17b and S22b in FIG. 7. The period C is shorter than the period B. The period C is so set that the first selection signal SS1 and the second selection signal SS2 are switched from ON to OFF and vice versa in the middle of each pulse of the pumping laser light Pu, as shown in FIG. 6. The pulse temporal waveform of each pulse of the first pulse laser light Lb1 is thus a waveform including a portion including the first seed laser light Sd1 and a portion including the second seed laser light Sd2. The period C may be so set that the first selection signal SS1 and the second selection signal SS2 are switched from ON to OFF and vice versa at the timing when the pulse temporal waveform of the pumping laser light Pu peaks.

The pulses p1 and p3 contained in the output laser light Out each have a wavelength of (λ1)/4 in the first half of the pulse temporal waveform of the pulse and a wavelength of (λ2)/4 in the second half of the pulse temporal waveform of the pulse.

The pulses p2 and p4 contained in the output laser light Out each have the wavelength of (λ2)/4 in the first half of the pulse temporal waveform of the pulse and the wavelength of (λ1)/4 in the second half of the pulse temporal waveform of the pulse.

The period required to switch the optical switch 50 is, for example, several nanoseconds. Assuming that the pulse temporal width of the first pulse laser light Lb1 is 40 ns, the wavelength of the output laser light Out can be reliably switched in the middle of the pulse.

### 3.2 Effects

According to the first variation of the first embodiment, the timing at which the optical switch 50 selects one of the first seed laser light Sd1 and the second seed laser light Sd2 is so controlled that the pulse temporal waveform of each pulse of the first pulse laser light Lb1 has the portion including the first seed laser light Sd1 and the portion including the second seed laser light Sd2. The configuration described above, in which one pulse contains a plurality of wavelength components, allows more frequent wavelength switching.

As for the other points, the first variation is the same as the example shown in FIGS. 3 to 5.

### 4. Laser Apparatus Capable of Adjusting Ratio Between Light Intensities of Wavelength Components

### 4.1 Operation

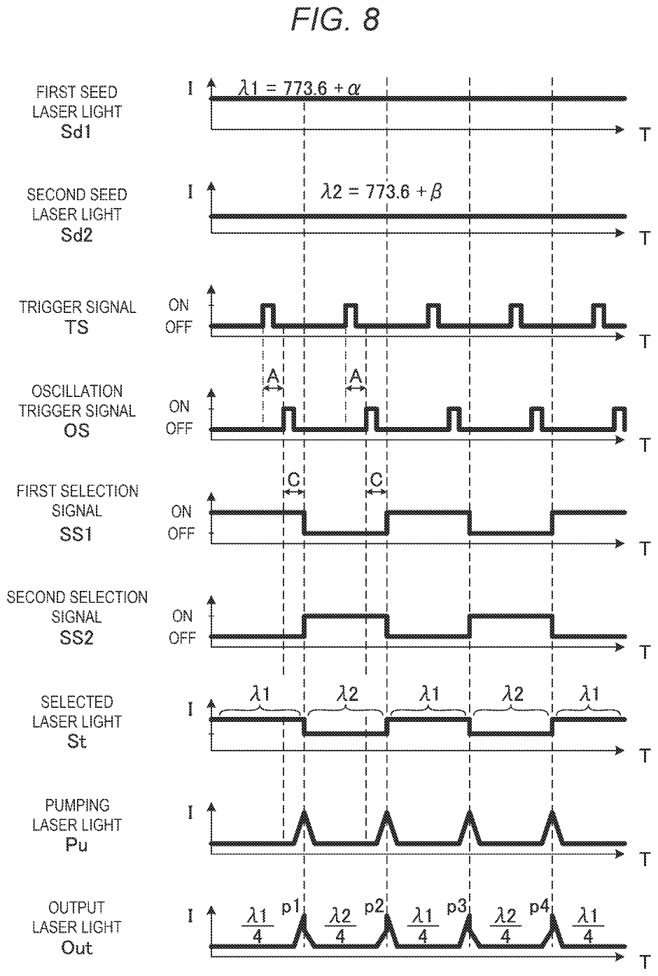

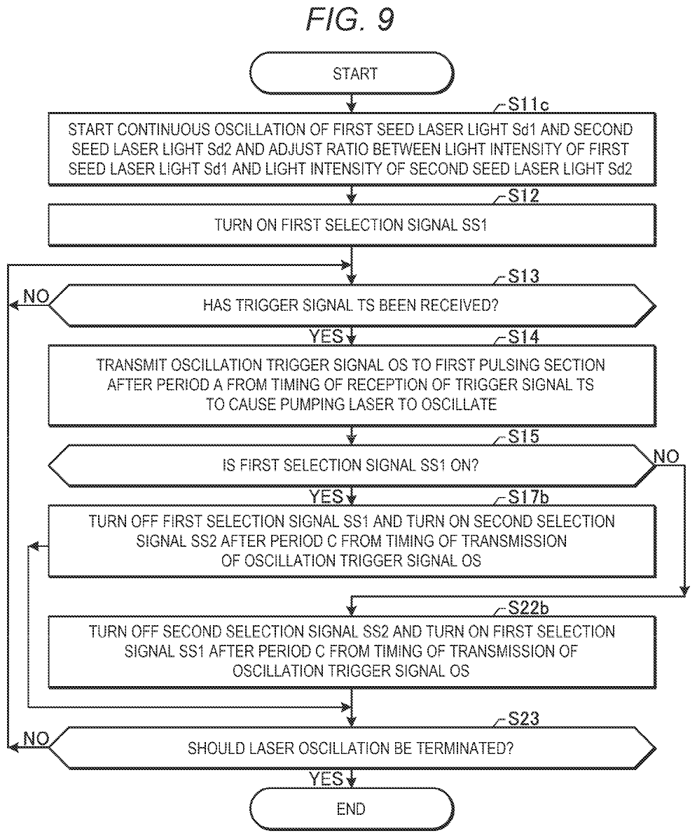

FIG. 8 is a timing chart in accordance with which the laser apparatus 100a according to a second variation of the first embodiment operates. FIG. 9 is a flowchart showing the procedure of processes carried out by the laser control processor 130 in the second variation. The configuration of the second variation is the same as the configuration shown in FIG. 3.

The second variation differs from the first variation in terms of the ratio between the light intensity of the first seed laser light Sd1 and the light intensity of the second seed laser light Sd2.

The laser control processor 130 starts continuous oscillation of the first seed laser light Sd1 and the second seed laser light Sd2, and adjusts the ratio between the light intensity of the first seed laser light Sd1 and the light intensity of the second seed laser light Sd2, as shown in S11c in FIG. 9. The light intensity I of the second seed laser light Sd2 is adjusted, for example, to be smaller than that of the first seed laser light Sd1, as shown in FIG. 8. In this case, the light intensity I of the selected laser light St is lower during the period for which the second seed laser light Sd2 having the wavelength λ2 is selected than during the period for which the first seed laser light Sd1 having the wavelength λ1 is selected.

When the optical switch 50 switches the seed laser light at the same timing as in the first variation, the portion including the second seed laser light Sd2 out of the pulse temporal waveform is smaller in terms of the light intensity I than the portion including the first seed laser light Sd1 out of the pulse temporal waveform of each pulse of the first pulse laser light Lb1.

The laser apparatus 100a can therefore be so controlled that the wavelength component having the first converted wavelength and the wavelength component having the second converted wavelength out of the output laser light Out differ from each other in terms of the accumulated energy.

The case where the ratio between the light intensity of the first seed laser light Sd1 and the light intensity of the second seed laser light Sd2 is adjusted has been described in FIGS. 8 and 9, but not necessarily in the present disclosure. The optical switch 50 may be so controlled that the transmittance of the optical switch 50 that selects the first seed laser light Sd1 differs from the transmittance of the optical switch 50 that selects the second seed laser light Sd2. In this case, even when the ratio between the light intensity of the first seed laser light Sd1 and the light intensity of the second seed laser light Sd2 is the same, the same selected laser light St and output laser light Out as those in FIG. 8 are provided.

### 4.2 Effects

According to the second variation of the first embodiment, the ratio between the light intensity of the first seed laser light Sd1 and the light intensity of the second seed laser light Sd2 is so adjusted that the wavelength component having the first converted wavelength and the wavelength component having the second converted wavelength out of the output laser light Out differ from each other in terms of the accumulated energy. The distribution of the image formation performance in the thickness direction of the photoresist film can thus be adjusted.

In the second variation, the optical switch 50 may be so controlled that the transmittance of the optical switch 50 that selects the first seed laser light Sd1 differs from the transmittance of the optical switch 50 that selects the second seed laser light Sd2. The light intensity I of the selected laser light St can therefore be changed in accordance with the wavelength switching even when the first seed laser light Sd1 and the second seed laser light Sd2 have the same light intensity. The laser apparatus 100a can therefore be so controlled that the wavelength component having the first converted wavelength and the wavelength component having the second converted wavelength out of the output laser light Out differ from each other in terms of the accumulated energy to adjust the distribution of the image formation performance in the thickness direction of the photoresist film.

As for the other points, the second variation is the same as the first variation.

### 5. Laser Apparatus That Adjusts Pulse Energy of Pumping Laser Light

### 5.1 Operation

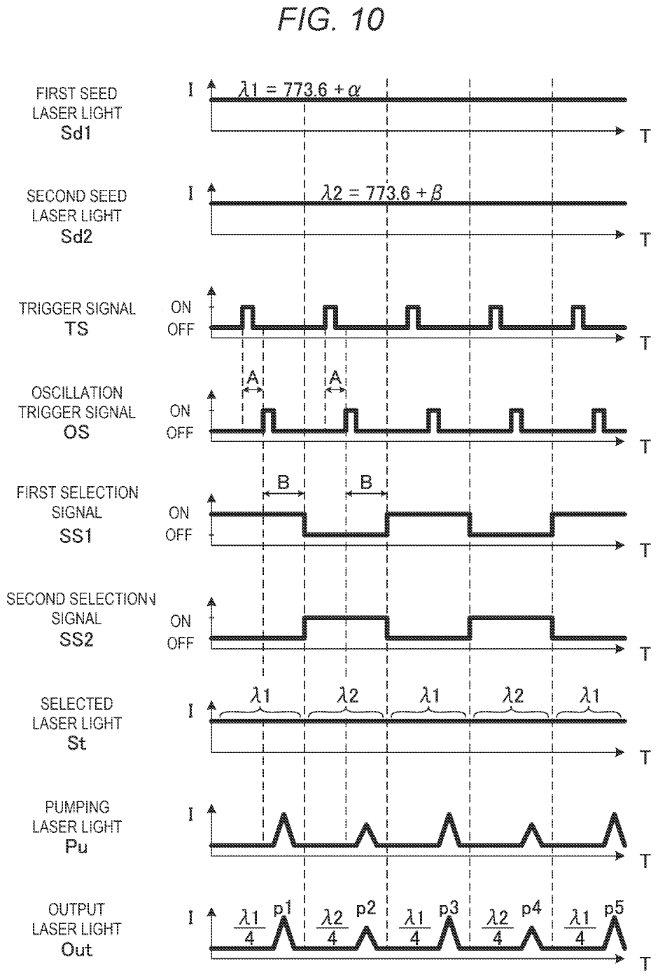

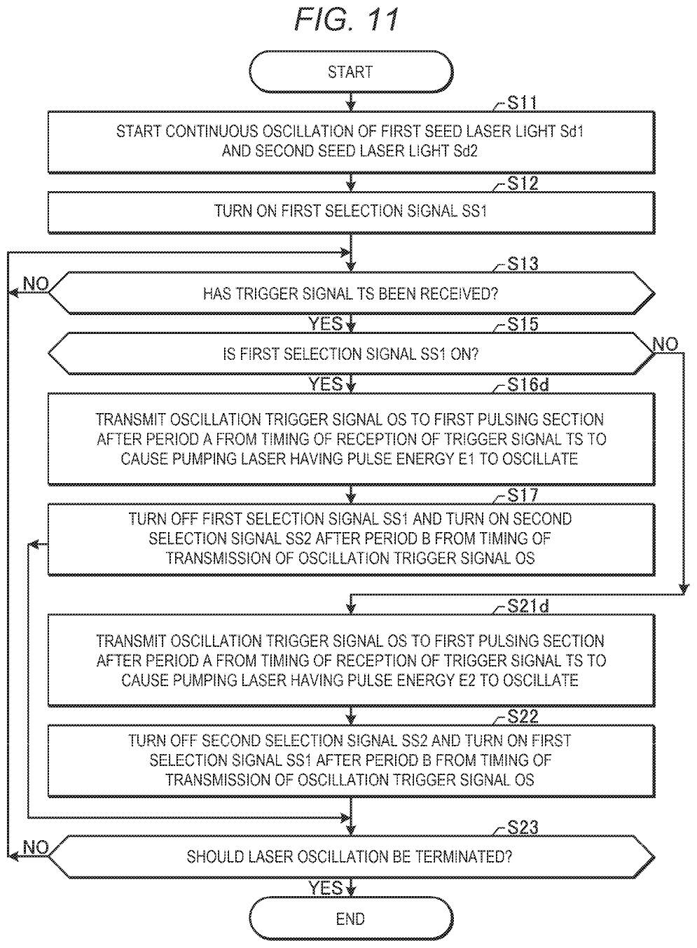

FIG. 10 is a timing chart in accordance with which the laser apparatus 100a according to a third variation of the first embodiment operates. FIG. 11 is a flowchart showing the procedure of processes carried out by the laser control processor 130 in the third variation. The configuration of the third variation is the same as the configuration shown in FIG. 3.

The third variation differs from the example shown in FIGS. 3 to 5 in that the pulse energy of the pumping laser light Pu is switched from a value to another.

For example, the pumping laser 60a is so controlled that the pulse energy of the pumping laser light Pu provided when the second seed laser light Sd2 is selected is smaller than the pulse energy of the pumping laser light Pu provided when the first seed laser light Sd1 is selected, as shown in FIG. 10. The pulse energy of the pulses p2 and p4 contained in the output laser light Out is thus smaller than the pulse energy of the pulses p1, p3, and p5 contained in the output laser light Out.

In the third variation, the pumping laser 60a is controlled differently depending on whether the first selection signal SS1 is ON (S15), as shown in FIG. 11. That is, in place of S14 shown in FIG. 5, the laser control processor 130 proceeds to the process in 516d before proceeding to the process in S17 when the first selection signal SS1 is ON (YES in S15). When the first selection signal SS1 is OFF (NO in S15), the laser control processor 130 proceeds to the process in S21d before proceeding to the process in S22.

In S16d, the laser control processor 130 transmits the oscillation trigger signal OS to the first pulsing section 60 after the period A from the timing of the reception of the trigger signal TS to cause the pumping laser 60a having a pulse energy E1 to oscillate.

In S21d, the laser control processor 130 transmits the oscillation trigger signal OS to the first pulsing section 60 after the period A from the timing of the reception of the trigger signal TS to cause the pumping laser 60a having a pulse energy E2 to oscillate. E1 and E2 have different values.

### 5.2 Effects

According to the third variation of the first embodiment, the pumping laser 60a is so controlled that the pulse energy E2 of the pumping laser light Pu provided when the optical switch 50 selects the second seed laser light Sd2 is smaller than the pulse energy E1 of the pumping laser light Pu provided when the optical switch 50 selects the first seed laser light Sd1. The laser apparatus 100a can therefore be so controlled that the wavelength component having the first converted wavelength and the wavelength component having the second converted wavelength out of the output laser light Out differ from each other in terms of the accumulated energy to adjust the distribution of the image formation performance in the thickness direction of the photoresist film.

As for the other points, the third variation is the same as the example shown in FIGS. 3 to 5.

### 6. Laser Apparatus That Includes Third Seed Laser and Oscillates at Plurality of Wavelengths

### 6.1 Configuration

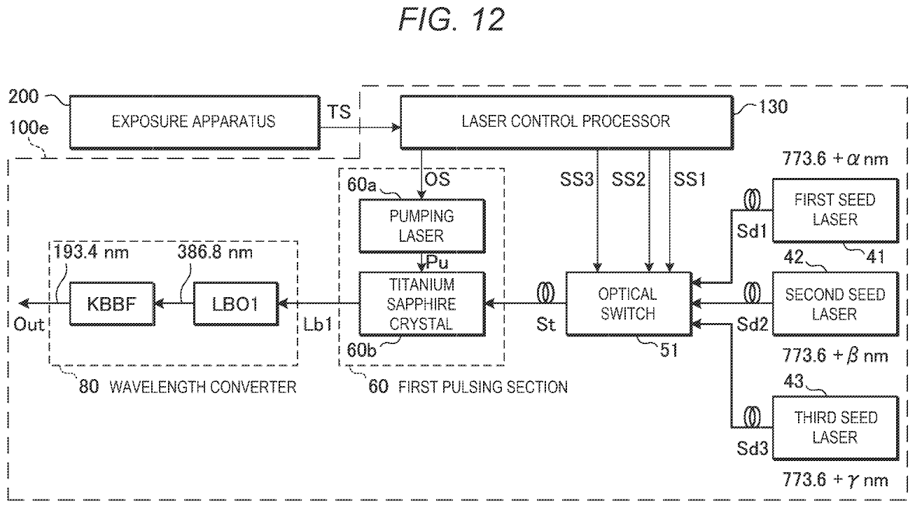

FIG. 12 schematically shows the configuration of a laser apparatus 100e according to a second embodiment. The laser apparatus 100e includes a third seed laser 43 in addition to the first seed laser 41 and the second seed laser 42.

The third seed laser 43 is, for example, a solid-state laser such as a semiconductor laser and configured to output continuous-wave third seed laser light Sd3 having a third oscillation wavelength λ3. The wavelength λ3 slightly differs from both the wavelengths λ1 and λ2, and is, for example, 773.600+γ nm. The constant γ may be 0.008 nm.

An optical switch 51 is configured to sequentially select the first seed laser light Sd1 to the third seed laser light Sd3 one at a time and output the selected seed laser light as the selected laser light λ3. The optical switch 51 selects the third seed laser light Sd3 when a third selection signal SS3 received from the laser control processor 130 is ON. The timing at which the optical switch 51 sequentially selects the first seed laser light Sd1 to the third seed laser light Sd3 one at a time is controlled by the laser control processor 130. As for the other points, the optical switch 51 is the same as the optical switch 50 (see FIG. 3).

The configuration of the first pulsing section 60 is the same as the corresponding configuration in the first embodiment.

The wavelength converter 80 performs the wavelength conversion using the first pulse laser light Lb1 and outputs the output laser light Out.

When the wavelength λ3 of the third seed laser light Sd3 is set at 773.608 nm, the crystals LBO1 and KBBF contained in the wavelength converter 80 convert the light having the wavelength λ3 into the output laser light Out having a wavelength of 193.402 nm. The wavelength as a result of the wavelength conversion of the wavelength λ3 is not shown. The wavelength of 193.402 nm is an example of the third converted wavelength in the present disclosure.

### 6.2 Operation

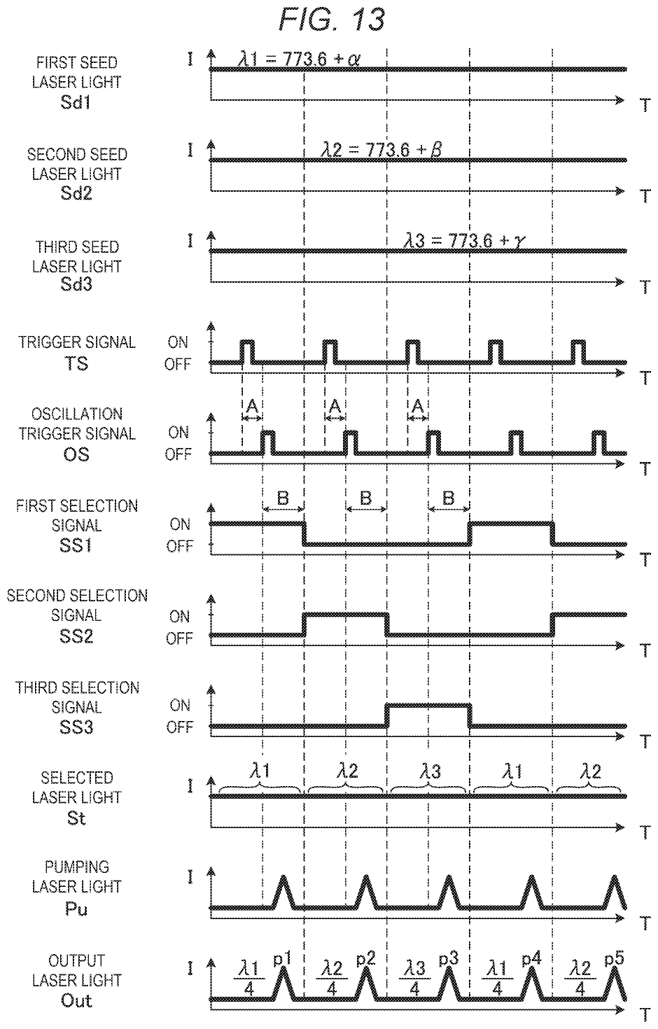

FIG. 13 is a timing chart in accordance with which the laser apparatus 100e according to the second embodiment operates. In FIG. 13, the third seed laser light Sd3 and the third selection signal SS3 are added to FIG. 4.

The third seed laser light Sd3 is continuous-wave laser light having light intensity I equal to those of the first seed laser light Sd1 and the second seed laser light Sd2 and the wavelength λ3 different from those of the first seed laser light Sd1 and the second seed laser light Sd2.

The first selection signal SS1 to the third selection signal SS3 are signals that sequentially become ON one at a time, and when one of the selection signals is ON, the other two are OFF. After the period B from the timing of the transmission of the oscillation trigger signal OS, the first selection signal SS1 to the third selection signal SS3 are switched from ON to OFF and vice versa and transmitted to the optical switch 51.

The selected laser light St has the wavelength λ1 during the period for which the first selection signal SS1 is ON, has the wavelength λ2 during the period for which the second selection signal SS2 is ON, and has the wavelength λ3 during the period for which the third selection signal SS3 is ON.

The pulses p1 and p4 contained in the output laser light Out are generated during the period for which the wavelength of the selected laser light St is λ1, and have the wavelength of (λ1)/4. The pulses p2 and p5 contained in the output laser light Out are generated during the period for which the wavelength of the selected laser light St is λ2, and have the wavelength of (λ2)/4. The pulse p3 contained in the output laser light Out are generated during the period for which the wavelength of the selected laser light St is λ3, and have a wavelength of (λ3)/4.

The wavelength (λ3)/4 is an example of the third converted wavelength in the present disclosure.

### 6.3 Process Procedure

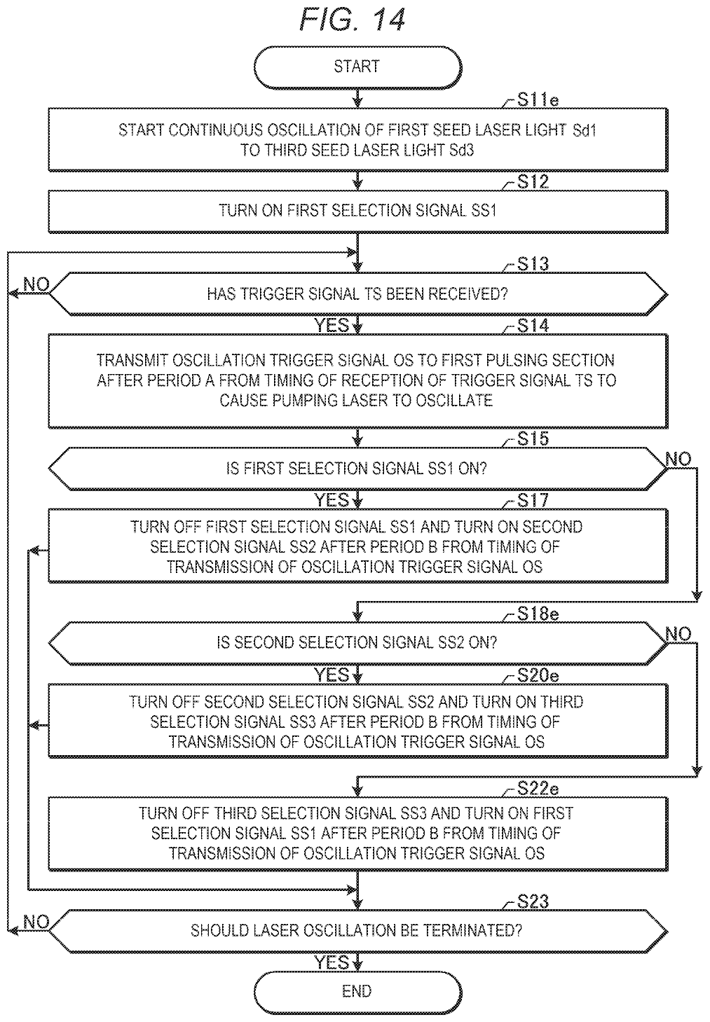

FIG. 14 is a flowchart showing the procedure of processes carried out by the laser control processor 130 in the second embodiment.

In S11e, the laser control processor 130 starts continuous oscillation of the first seed laser light Sd1 to the third seed laser light Sd3.

The processes in S12 to S17 are the same as those in the example shown in FIG. 5.

When the first selection signal SS1 is OFF in S15 (NO in S15), the laser control processor 130 proceeds to the process in S18e.

In S18e, the laser control processor 130 evaluates whether the second selection signal SS2 is ON. When the second selection signal SS2 is ON (YES in S18e), the laser control processor 130 proceeds to the process in S20e. When the second selection signal SS2 is OFF (NO in S18e), the laser control processor 130 proceeds to the process in S22e.

In S20e, the laser control processor 130 turns off the second selection signal SS2 and turns on the third selection signal SS3 after the period B from the timing of the transmission of the oscillation trigger signal OS. After S20e, the laser control processor 130 proceeds to the process in S23.

In S22e, the laser control processor 130 turns off the third selection signal SS3 and turns on the first selection signal SS1 after the period B from the timing of the transmission of the oscillation trigger signal OS. After S22e, the laser control processor 130 proceeds to the process in S23.

The process in S23 is the same as that in the example shown in FIG. 5.

### 6.4 Effects

According to the second embodiment, the first seed laser light Sd1 to the third seed laser light Sd3 are sequentially selected one at a time by the optical switch 51, pulsed, and then converted in terms of wavelength. Since the output laser light Out containing three wavelength peaks is thus output to the exposure apparatus 200, a deep depth of focus is achieved in the photoresist film.

As for the other points, the second embodiment is the same as the first embodiment or any of the variations thereof.

### 7. Laser Apparatus That Performs Wavelength Conversion Through Sum-Frequency Mixing

### 7.1 Configuration

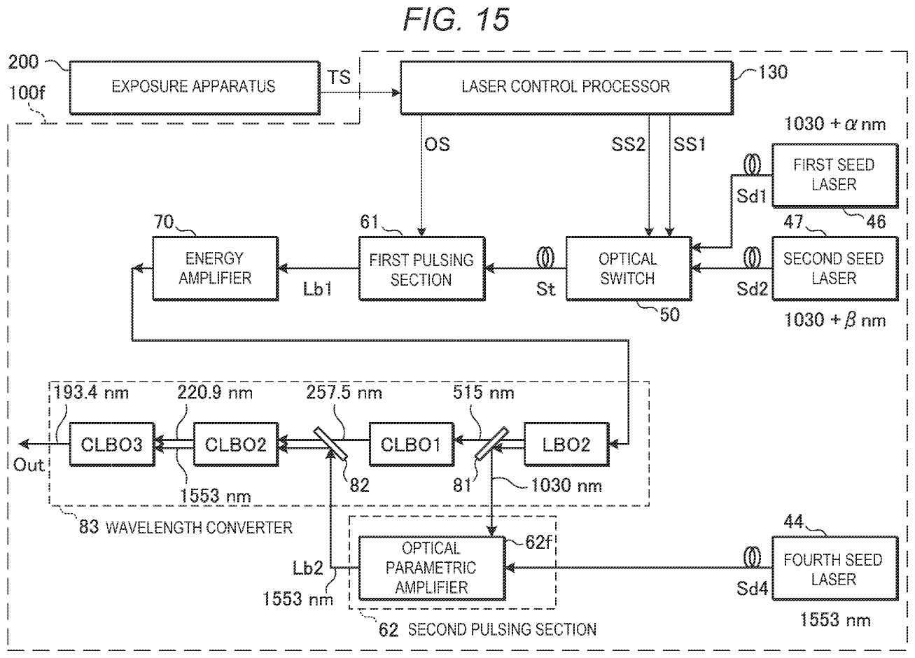

FIG. 15 schematically shows the configuration of a laser apparatus 100f according to a third embodiment. The laser apparatus 100f includes a first seed laser 46, a second seed laser 47, a first pulsing section 61, and a wavelength converter 83 in place of the first seed laser 41, the second seed laser 42, the first pulsing section 60, and the wavelength converter 80. The laser apparatus 100f further includes a fourth seed laser 44, an energy amplifier 70, and a second pulsing section 62.

The wavelength λ1 of the first seed laser light Sd1 output from the first seed laser 46 is, for example, 1030.000+α nm, and the wavelength λ2 of the second seed laser light Sd2 output from the second seed laser 47 is, for example, 1030.000+βnm. The wavelengths λ1 and λ2 are each longer than or equal to 1029 nm but shorter than or equal to 1032 nm, and the difference between the wavelengths λ1 and λ2 may be greater than or equal to 1 μm but smaller than or equal to 110 μm. The constant a may be 0.000 nm, and the constant β may be 0.008 nm.

The first pulsing section 61 includes a drive circuit, an electro-optical element, and a polarizer, none of which is shown. In accordance with the oscillation trigger signal OS, the drive circuit generates a drive signal to be applied to the electro-optical element. The electro-optical element is an element that changes the polarization state of the light passing therethrough in accordance with the drive signal. The polarizer is disposed in the optical path of the light having passed through the electro-optical element. When the oscillation trigger signal OS becomes OFF, the drive signal becomes OFF, and the light having passed through the electro-optical element is blocked by the polarizer and enters the laser damper, which is not shown. When the oscillation trigger signal OS becomes ON, the drive signal becomes ON for a certain period, and the light having passed through the electro-optical element passes through the polarizer. The first pulsing section 61 thus extracts the first pulse laser light Lb1 from the selected laser light St. The pulse temporal width of the first pulse laser light Lb1 is controlled by the pulse temporal width of the drive signal, for example, longer than or equal to 10 ns but shorter than or equal to 40 ns. The first pulse laser light Lb1 enters the energy amplifier 70.

The energy amplifier 70 may, for example, be a fiber laser amplifier doped with ytterbium, or an amplifier including an yttrium aluminum garnet (YAG) crystal doped with ytterbium. The first pulsing section 61 does not amplify the selected laser light St, but the energy amplifier 70 instead amplifies the first pulse laser light Lb1 and causes the amplified first pulse laser light Lb1 to enter the wavelength converter 83.

The fourth seed laser 44 is, for example, a solid-state laser such as a semiconductor laser and configured to output continuous-wave fourth seed laser light Sd4 having a fourth oscillation wavelength λ4. The wavelength λ4 is, for example, 1553 nm.

The second pulsing section 62 includes an optical parametric amplifier 62f disposed in the optical path of the fourth seed laser light Sd4. The optical parametric amplifier 62f contains a periodically poled lithium niobate (PPLN) crystal.

The wavelength converter 83 includes a nonlinear optical crystal for performing wavelength conversion using the first pulse laser light Lb1 and the second pulse laser light Lb2 and outputting the output laser light Out. The nonlinear optical crystal includes, for example, a crystal LBO2 made of LBO, and crystals CLBO1, CLBO2, and CLBO3 made of cesium lithium borate (CLBO). The wavelength converter 83 further includes dichroic mirrors 81 and 82. The dichroic mirror 81 is disposed between the crystal LBO2 and the crystal CLBO1, and the dichroic mirror 82 is disposed between the crystal CLBO1 and the crystal CLBO2. The crystal CLBO2 or CLBO3 corresponds to the first nonlinear optical crystal in the present disclosure.

### 7.2 Operation

The second pulsing section 62 pulses the fourth seed laser light Sd4 and outputs the second pulse laser light Lb2 toward the wavelength converter 83. The wavelength of the second pulse laser light Lb2 is equal to the wavelength of the fourth seed laser light Sd4, for example, 1553 nm.

The crystal LBO2 is located in the optical path of the first pulse laser light Lb1 between the first pulsing section 61 and the dichroic mirror 81. The crystal LBO2 corresponds to the second nonlinear optical crystal in the present disclosure.

When the wavelength λ1 is set at 1030.000 nm and the wavelength λ2 is set at 1030.008 nm, the crystal LBO2 outputs a fundamental wave component having a wavelength of 1030.000 nm or 1030.008 nm, and a second harmonic component having a wavelength of 515.000 nm or 515.004 nm toward the dichroic mirror 81. In the following description, the wavelengths λ1 and λ2 may not be distinguished from each other but may be collectively expressed by an approximate number.

The dichroic mirror 81 reflects the fundamental wave component having the wavelength of 1030 nm toward the optical parametric amplifier 62f, and transmits the second harmonic component having the wavelength of 515 nm toward the crystal CLBO2 via the crystal CLBO1 to split the first pulse laser light Lb1. The dichroic mirror 81 corresponds to the beam splitter in the present disclosure.

The optical parametric amplifier 62f generates the second pulse laser light Lb2 in accordance with the timing at which the first pulse laser light Lb1 received from the dichroic mirror 81 is incident on the optical parametric amplifier 62f, and outputs the second pulse laser light Lb2 through the dichroic mirror 82 toward the crystal CLBO2. The pulse temporal width of the second pulse laser light Lb2 is equal to the pulse temporal width of the first pulse laser light Lb1, for example, longer than or equal to 10 ns but shorter than or equal to 40 ns. The dichroic mirror 82 corresponds to the beam combiner in the present disclosure.

The crystal CLBO1 is located in the optical path of the first pulse laser light Lb1 between the dichroic mirror 81 and the crystal CLBO2. The crystal CLBO1 corresponds to the third nonlinear optical crystal in the present disclosure.

The crystal CLBO1 converts the light having the wavelength of 515 nm in terms of wavelength into light having a wavelength of 257.5 nm, which is the second harmonic of the incident light, and outputs the converted light toward the dichroic mirror 82.

The dichroic mirror 82 transmits the first pulse laser light Lb1 having the wavelength of 257.5 nm output from the crystal CLBO1, and reflects the second pulse laser light Lb2 having the wavelength of 1553 nm output from the optical parametric amplifier 62f. The dichroic mirror 82 thus causes the optical path of the first pulse laser light Lb1 and the optical path of the second pulse laser light Lb2 to coincide with each other so that they enter the crystal CLBO2.

The crystal CLBO2 outputs the light having the wavelength of 1553 nm as the fundamental wave component, causes the light having the wavelength of 1553 nm and the light having the wavelength of 257.5 nm to undergo sum-frequency mixing to output light having a wavelength of 220.9 nm as shown by the following expression, and causes the two kinds of output light to enter the crystal CLBO3.

1/(1/1553+1/257.5) [symbol] 220.9

The crystal CLBO3 outputs the output laser light Out having the wavelength of 193.4 nm as shown by the following expression through sum-frequency mixing of the light having the wavelength of 1553 nm and the light having the wavelength of 220.9 nm.

1/(1/1553+1/220.9) [symbol] 193.4

The wavelength of 193.4 nm is an example of the first converted wavelength in the present disclosure. The wavelength converter 83 thus outputs the output laser light Out having the first converted wavelength through the wavelength conversion using the near-infrared wavelengths λ1 and λ4. The wavelength converter 83 outputs the output laser light Out having the second converted wavelength through the wavelength conversion using the near-infrared wavelengths λ2 and λ4. When the difference between the wavelengths λ1 and λ2 is set at 8 pm, the difference between the first converted wavelength and the second converted wavelength is approximately 1 pm. The first and second converted wavelengths are approximately equal to the wavelength of the light output from an ArF excimer laser apparatus.

### 7.3 Effects

According to the third embodiment, the wavelength converter 83 performs wavelength conversion by using not only the first pulse laser light Lb1 but also the second pulse laser light Lb2, which is produced by pulsing the fourth seed laser light Sd4. The flexibility of the wavelength conversion is thus improved, so that a desired converted wavelength can be produced.

According to the third embodiment, the second pulsing section 62 outputs the second pulse laser light Lb2 in accordance with the timing at which the first pulse laser light Lb1 split by the dichroic mirror 81 enters the second pulsing section 62. The timing at which the second pulse laser light Lb2 is output can thus be precisely controlled.

According to the third embodiment, the crystal LBO2 is disposed between the first pulsing section 61 and the dichroic mirror 81. Therefore, out of the fundamental wave component and the harmonic wave component output from the crystal LBO2, the fundamental wave component can be used to control the second pulsing section 62, and the harmonic wave component can be used for the wavelength shortening performed by the wavelength converter 83. The pulse energy of the first pulse laser light Lb1 can therefore be effectively used.

According to the third embodiment, the wavelength converter 83 includes the crystal CLBO1 and the dichroic mirror 82. A desired converted wavelength can thus be produced.

As for the other points, the third embodiment is the same as the first embodiment or any of the variations thereof. Instead, the wavelength conversion may be performed by using not only the first pulse laser light Lb1 produced by sequentially selecting one at a time and pulsing the first seed laser light Sd1 to the third seed laser light Sd3 but also the second pulse laser light Lb2, as in the second embodiment.

### 8. Laser Apparatus that Changes Posture of Nonlinear Optical Crystal in Synchronization with Wavelength Switching

### 8.1 Configuration and Operation

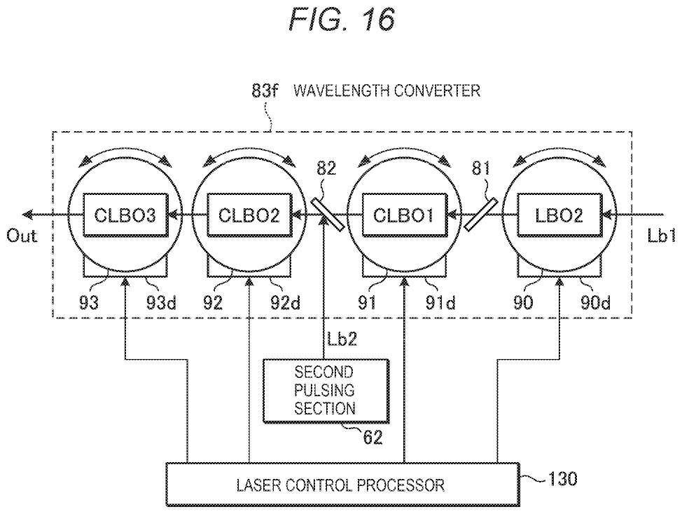

FIG. 16 schematically shows the configuration of a wavelength converter 83f according to a first variation of the third embodiment. The wavelength converter 83f is provided in the laser apparatus 100f in place of the wavelength converter 83 shown in FIG. 15. The crystals LBO2, CLBO1, CLBO2, and CLBO3 arranged along the optical path of the first pulse laser light Lb1 in the wavelength converter 83f are supported by holders 90, 91, 92, and 93, respectively, and are configured to be rotatable by drive mechanisms 90d, 91d, 92d, and 93d, respectively. The drive mechanisms 90d, 91d, 92d, and 93d are controlled by the laser control processor 130. The axes of rotation of the crystals LBO2, CLBO1, CLBO2, and CLBO3 may be perpendicular to the optical path axis of the first pulse laser light Lb1.

The switching performed by the optical switch 50 between the first seed laser light Sd1 and the second seed laser light Sd2 causes the wavelengths λ1 and λ2 of the first pulse laser light Lb1 that enters the wavelength converter 83f to be switched from one to the other. The wavelength switching changes the phase matching conditions required for the crystals LBO2, CLBO1, CLBO2, and CLBO3 to perform the wavelength conversion. When the difference between the first and second converted wavelengths increases to 1 pm or greater, the change in the phase matching conditions also increases. In view of the fact described above, it is desirable that the angles of incidence of the first pulse laser light Lb1 incident on the crystals LBO2, CLBO1, CLBO2, and CLBO3 be adjusted to meet the phase matching conditions. The postures of the crystals LBO2, CLBO1, CLBO2, and CLBO3 are changed in synchronization with the timing at which the optical switch 50 sequentially selects the first seed laser light Sd1 and the second seed laser light Sd2 one at a time.

### 8.2 Effects

According to the first variation of the third embodiment, the wavelength converter 83f includes the drive mechanisms 90d, 91d, 92d, and 93d, which rotate the crystals LBO2, CLBO1, CLBO2, and CLBO3, respectively. The drive mechanisms 90d, 91d, 92d, and 93d are controlled in synchronization with the timing at which the optical switch 50 switches the seed laser light from the first seed laser light Sd1 to the second seed laser light Sd2 and vice versa. The angles of incidence of the first pulse laser light Lb1 incident on the crystals LBO2, CLBO1, CLBO2, and CLBO3 can thus be adjusted in accordance with the change in the phase matching conditions due to the wavelength switching.

As for the other points, the first variation of the third embodiment is the same as the example shown in FIG. 15.

### 9. Laser Apparatus with First and Third Pulsing Sections Disposed Upstream From Optical Switch

### 9.1 Configuration and Operation

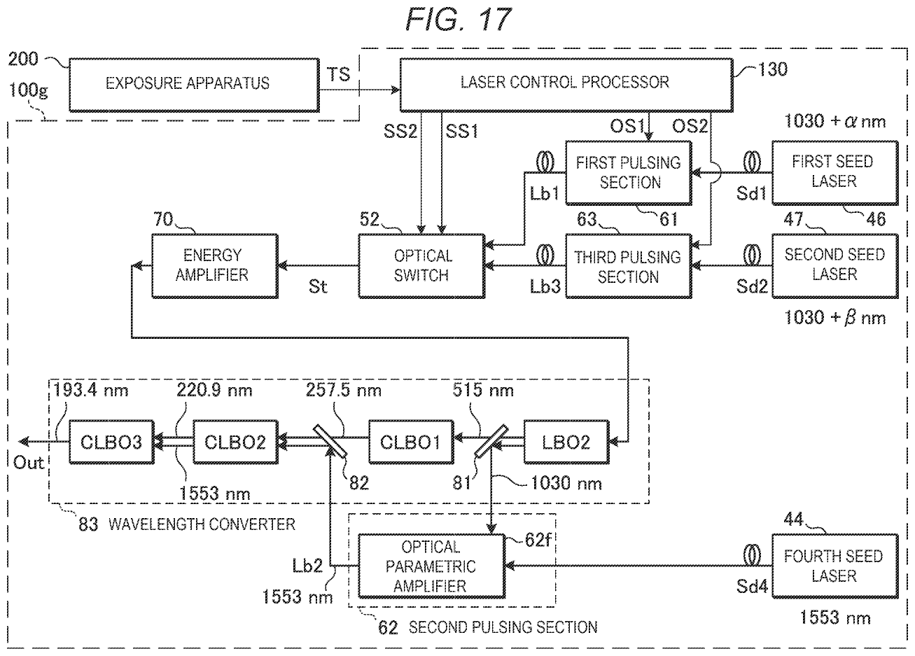

FIG. 17 schematically shows the configuration of a laser apparatus 100g according to a second variation of the third embodiment. The laser apparatus 100g includes a third pulsing section 63 disposed in the optical path of the second seed laser light Sd2. The first pulsing section 61 is disposed in the optical path of the first seed laser light Sd1.

An optical switch 52 is disposed in the optical path of the first pulse laser light Lb1 pulsed by the first pulsing section 61 and the third pulse laser light Lb3 pulsed by the third pulsing section 63. The optical switch 52 is configured to sequentially select the first pulse laser light Lb1 and the third pulse laser light Lb3 one at a time and output the selected seed laser light as the pulse-shaped selected laser light St. As for the other points, the optical switch 52 is the same as the optical switch 50 (see FIG. 3).

As for the other points, the second variation of the third embodiment is the same as the example shown in FIG. 15. Note, however, that the second variation differs from the example shown in FIG. 15 in that the selected laser light St is used in place of the first pulse laser light Lb1 in the operation of the energy amplifier 70 and the wavelength converter 83.

### 9.2 Effects

According to the second variation of the third embodiment, the first seed laser light Sd1 and the second seed laser light Sd2 are pulsed to form the first pulse laser light Lb1 and the third pulse laser light Lb3, respectively, and the first pulse laser light Lb1 and the third pulse laser light Lb3 are sequentially selected one at a time by the optical switch 52 and converted in terms of wavelength. The configuration described above, in which the optical switch 52 can operate at high speed, allows high-speed switching between the first and second conversion wavelengths contained in the output laser light Out. Furthermore, since the first seed laser light Sd1 and the second seed laser light Sd2 are continuous-wave laser light and have stable energy, it can be expected that the pulse energy of the output laser light Out is also stable.

According to the second variation, the wavelength converter 83 performs the wavelength conversion by using not only the selected laser light St, which is produced by sequentially selecting the first pulse laser light Lb1 and the third pulse laser light Lb3 one at a time, but also the second pulse laser light Lb2, which is produced by pulsing the fourth seed laser light Sd4. The flexibility of the wavelength conversion is thus improved, so that a desired converted wavelength can be produced.

According to the second variation, the second pulsing section 62 outputs the second pulse laser light Lb2 in accordance with the timing at which the selected laser light St split by the dichroic mirror 81 enters the second pulsing section 62. The timing at which the second pulse laser light Lb2 is output can thus be precisely controlled.

### 10. Laser Apparatus That Pulses Selected Laser Light With Optical Parametric Amplifier

### 10.1 Configuration and Operation

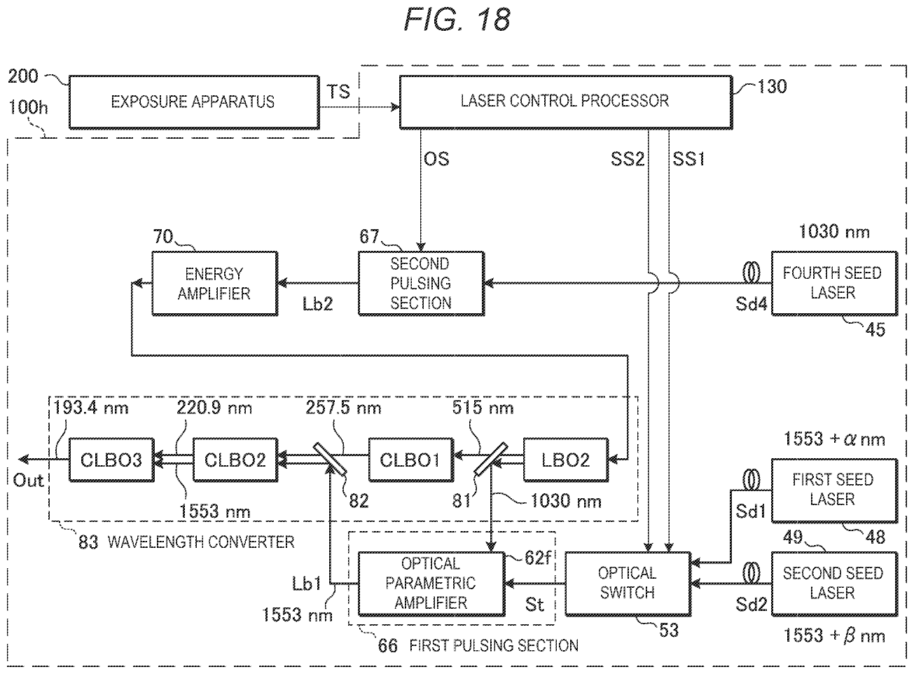

FIG. 18 schematically shows the configuration of a laser apparatus 100h according to a fourth embodiment. The laser apparatus 100h includes a first seed laser 48, a second seed laser 49, a fourth seed laser 45, an optical switch 53, a first pulsing section 66, a second pulsing section 67, the energy amplifier 70, the wavelength converter 83, and the laser control processor 130.

The first seed laser 48 and the second seed laser 49 are each formed, for example, of a solid-state laser, such as a semiconductor laser. The first seed laser 48 is configured to output the continuous-wave first seed laser light Sd1 having the first oscillation wavelength λ1. The second seed laser 49 is configured to output the continuous-wave second seed laser light Sd2 having the second oscillation wavelength λ2. The wavelength λ1 is, for example, 1553.00+α nm, and the wavelength λ2 is, for example, 1553.00+β nm. The wavelengths λ1 and λ2 are each longer than or equal to 1490 nm but shorter than or equal to 1557 nm, and the difference between the wavelengths λ1 and λ2 may be greater than or equal to 1 pm but smaller than or equal to 110 pm. The constant α may be −0.20 nm, and the constant β may be −0.16 nm.

The optical switch 53 is configured to sequentially select the first seed laser light Sd1 and the second seed laser light Sd2 one at a time and output the selected seed laser light as the selected laser light St. The optical switch 53 selects the first seed laser light Sd1 when the first selection signal SS1 received from the laser control processor 130 is ON, and selects the second seed laser light Sd2 when the second selection signal SS2 received from the laser control processor 130 is ON. As described above, the timing at which the optical switch 53 sequentially selects the first seed laser light Sd1 and the second seed laser light Sd2 one at a time is controlled by the laser control processor 130.

The selected laser light St having been selected from the first seed laser light Sd1 and the second seed laser light Sd2 and having entered the optical switch 53, enters the first pulsing section 66. As for the other points, the optical switch 53 is the same as the optical switch 50 (see FIG. 3).

The first pulsing section 66 includes the optical parametric amplifier 62f disposed in the optical path of the selected laser light St. The configuration and operation of the optical parametric amplifier 62f are the same as those in the example shown in FIG. 15.

The first pulsing section 66 pulses the selected laser light St and outputs the first pulse laser light Lb1 toward the wavelength converter 83.

The fourth seed laser 45 is, for example, a solid-state laser such as a semiconductor laser and configured to output the continuous-wave fourth seed laser light Sd4 having the fourth oscillation wavelength λ4. The wavelength λ4 is, for example, 1030 nm. The fourth seed laser light Sd4 enters the second pulsing section 67.

The second pulsing section 67 includes a drive circuit, an electro-optical element, and a polarizer, none of which is shown. The configuration and operation of each of the drive circuit, the electro-optical element, and the polarizer are the same as those of the corresponding component accommodated in the first pulsing section 61 shown in FIG. 15. Note, however, that the second pulsing section 67 extracts the second pulse laser light Lb2 from the fourth seed laser light Sd4. The second pulse laser light Lb2 enters the energy amplifier 70.

The configuration and operation of the energy amplifier 70 and the wavelength converter 83 are the same as those in the example shown in FIG. 15. Note, however, that the first pulse laser light Lb1 and the second pulse laser light Lb2 are swapped in FIGS. 15 and 18.

The wavelength converter 83 outputs the output laser light Out having the first converted wavelength produced by the wavelength conversion using the near-infrared wavelengths λ1 and λ4, and outputs the output laser light Out having the second converted wavelength produced by the wavelength conversion using the near-infrared wavelengths λ2 and λ4. When the difference between the wavelengths λ1 and λ2 is set at 40 pm, the difference between the first converted wavelength and the second converted wavelength is approximately 1 pm. The first and second converted wavelengths are approximately equal to the wavelength of the light output from an ArF excimer laser apparatus.

### 10.2 Effects

According to the fourth embodiment, the first pulsing section 66 outputs the first pulse laser light Lb1 in accordance with the timing at which the second pulse laser light Lb2 split by the dichroic mirror 81 enters the first pulsing section 66. The timing at which the first pulse laser light Lb1 is output can thus be precisely controlled.

According to the fourth embodiment, the crystal LBO2 is disposed between the second pulsing section 67 and the dichroic mirror 81. Therefore, out of the fundamental wave component and the harmonic wave component output from the crystal LBO2, the fundamental wave component can be used to control the first pulsing section 66, and the harmonic wave component can be used for the wavelength shortening performed by the wavelength converter 83. The pulse energy of the second pulse laser light Lb2 can therefore be effectively used.

According to the fourth embodiment, the wavelength converter 83 includes the crystal CLBO1 and the dichroic mirror 82. A desired converted wavelength can thus be produced.

As for the other points, the fourth embodiment is the same as the third embodiment.

### 11. Laser Apparatus That Changes Posture of Nonlinear Optical Crystal in Synchronization With Wavelength Switching

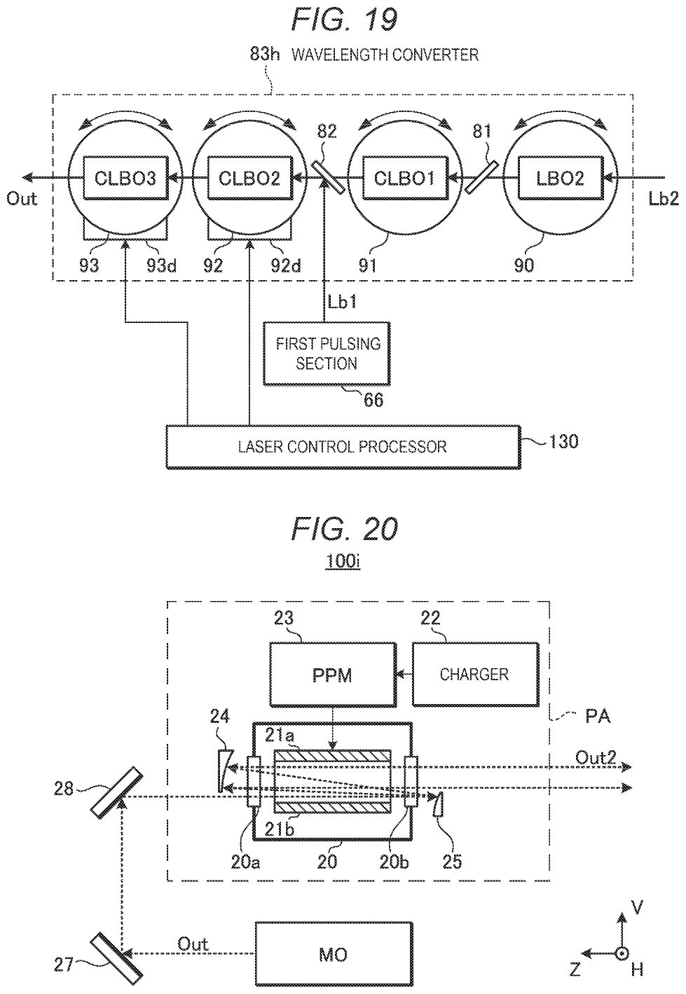

FIG. 19 schematically shows the configuration of a wavelength converter 83h according to a first variation of the fourth embodiment. The wavelength converter 83h is provided in the laser apparatus 100h in place of the wavelength converter 83 shown in FIG. 18. The crystals LBO2, CLBO1, CLBO2, and CLBO3 arranged along the optical path of the second pulse laser light Lb2 in the wavelength converter 83h are supported by the holders 90, 91, 92, and 93, respectively. Out of the crystals described above, the crystals CLBO2 and CLBO3 arranged along the optical path of the first pulse laser light Lb1 are configured to be rotatable by the drive mechanisms 92d and 93d, respectively. The drive mechanisms 92d and 93d are controlled by the laser control processor 130. The axes of rotation of the crystals CLBO2 and CLBO3 may be perpendicular to the optical path axis of the first pulse laser light Lb1.

The switching performed by the optical switch 53 between the first seed laser light Sd1 and the second seed laser light Sd2 causes the wavelengths λ1 and λ2 of the first pulse laser light Lb1 that enters the wavelength converter 83h to be switched from one to the other. The wavelength switching changes the phase matching conditions required for the crystals CLBO2 and CLBO3 to perform the wavelength conversion. When the difference between the first and second converted wavelengths increases to 1 pm or greater, the change in the phase matching conditions also increases. In view of the fact described above, it is desirable that the angles of incidence of the first pulse laser light Lb1 incident on the crystals CLBO2 and CLBO3 be adjusted to meet the phase matching conditions. The postures of the crystals CLBO2 and CLBO3 are changed in synchronization with the timing at which the optical switch 53 sequentially selects the first seed laser light Sd1 and the second seed laser light Sd2 one at a time.

As for the other points, the first variation of the fourth embodiment is the same as the example shown in FIG. 18.

### 12. Laser Apparatus Including Amplifier

### 12.1 Configuration

FIG. 20 schematically shows the configuration of a laser apparatus 100i according to a fifth embodiment. The laser apparatus 100i includes a master oscillator MO, an amplifier PA, and highly reflective mirrors 27 and 28. Any one of the laser apparatuses 100a, 100e, 100f, and 100h according to the first to fourth embodiments and the variations thereof is used as the master oscillator MO.

The amplifier PA is an ArF excimer laser apparatus including a laser chamber 20, a charger 22, a pulse power module 23, a concave cylindrical mirror 24, and a convex cylindrical mirror 25. The configurations of the laser chamber 20, the following components provided therein: windows 20a and 20b; and a pair of discharge electrodes 21a and 21b, the charger 22, and the pulse power module 23 are the same as corresponding configurations in the laser apparatus 100 described with reference to FIG. 2.

The convex cylindrical mirror 25 is disposed in the optical path of the output laser light Out output from the master oscillator MO, reflected off the highly reflective mirrors 27 and 28, and passing through the laser chamber 20.

The concave cylindrical mirror 24 is disposed in the optical path of the output laser light Out reflected off the convex cylindrical mirror 25 and passing through the laser chamber 20 again.

### 12.2 Operation

The output laser light Out having been output from the master oscillator MO and having entered the amplifier PA passes through the discharge space in the laser chamber 20, and is then reflected off the convex cylindrical mirror 25 with the reflected output laser light Out given a beam divergence angle according to the curvature of the convex cylindrical mirror 25. The output laser light Out passes again through the discharge space in the laser chamber 20.

The pulse laser light having been reflected off the convex cylindrical mirror 25 and having passed again through the laser chamber 20 is reflected off the concave cylindrical mirror 24 and returns to substantially parallelized light. The resultant output laser light Out passes one more time through the discharge space in the laser chamber 20.

When the output laser light Out enters the laser chamber 20 from the master oscillator MO, a high voltage is applied to the discharge electrode 21a so that discharge starts in the discharge space in the laser chamber 20. The beam width of the output laser light Out is increased by the convex cylindrical mirror 25 and the concave cylindrical mirror 24, and the resultant output laser light Out is amplified when passing through the discharge space three times, and is output as output laser light Out2 out of the laser apparatus 100i.

According to the fifth embodiment, increasing the beam width of the output laser light Out and amplifying the resultant output laser light Out allows the output laser light Out2 having high pulse energy to be output toward the exposure apparatus 200.

### 13. Laser Apparatus Including Ring Resonator

### 13.1 Configuration

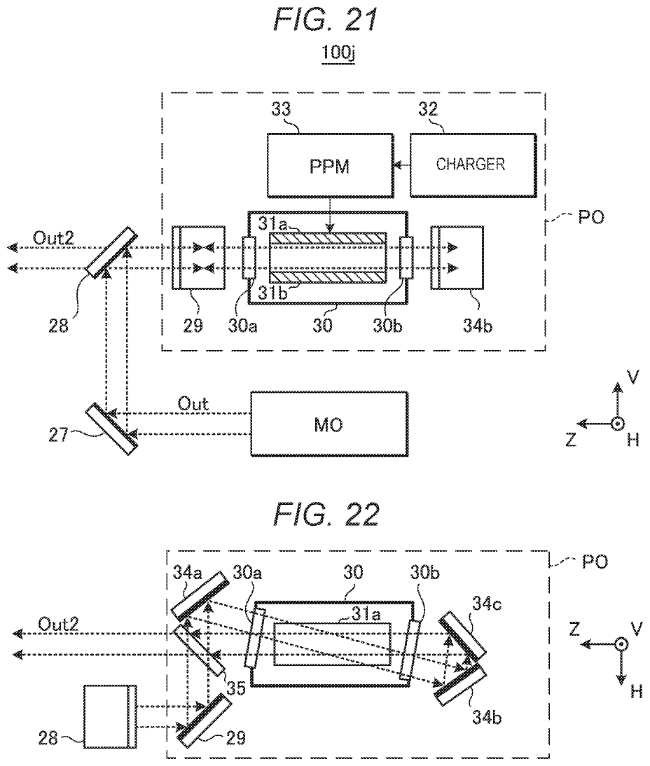

FIG. 21 schematically shows the configuration of a laser apparatus 100j according to a sixth embodiment. FIG. 22 shows a power oscillator PO shown in FIG. 21 viewed in a direction different from that in FIG. 21. The laser apparatus 100j includes the master oscillator MO, the power oscillator PO, and the highly reflective mirrors 27 and 28. Any one of the laser apparatuses 100a, 100e, 100f, and 100h according to the first to fourth embodiments and the variations thereof is used as the master oscillator MO.

The power oscillator PO is an ArF excimer laser apparatus including a laser chamber 30, a charger 32, a pulse power module 33, highly reflective mirrors 34a to 34c, an output coupling mirror 35, and a highly reflective mirror 29. The configurations of the laser chamber 30, the following components provided therein: windows 30a and 30b; and a pair of discharge electrodes 31a and 31b, the charger 32, and the pulse power module 33 are the same as corresponding configurations in the laser apparatus 100 described with reference to FIG. 2.

The output coupling mirror 35 and the highly reflective mirror 34a are disposed at positions outside the laser chamber 30 and near the window 30a. The highly reflective mirrors 34b and 34c are disposed at positions outside the laser chamber 30 and near the window 30b. In the discharge space between the discharge electrodes 31a and 31b, the optical path from the highly reflective mirror 34a to the highly reflective mirror 34b and the optical path from the highly reflective mirror 34c to the output coupling mirror 35 intersect with each other.

### 13.2 Operation

The output laser light Out output from the master oscillator MO is reflected off the highly reflective mirrors 27, 28, and 29 in this order, and is incident on the output coupling mirror 35 from the outside of the resonator of the power oscillator PO approximately in a −H direction. The output laser light Out having entered the resonator via the output coupling mirror 35 is reflected off the highly reflective mirrors 34a, 34b, and 34c in this order, is amplified when passing through the discharge space, and is incident on the output coupling mirror 35 in a Z direction from the interior of the resonator.

Part of the light incident on the output coupling mirror 35 in the Z direction is reflected approximately in the −H direction, reflected again off the highly reflective mirrors 34a, 34b, and 34c, and amplified. Other part of the light incident on the output coupling mirror 35 in the Z direction passes therethrough and is output as the output laser light Out2 toward the exposure apparatus 200.

According to the sixth embodiment, in which return light from the power oscillator PO toward the master oscillator MO is unlikely to be produced, the master oscillator MO can operate in a stable manner.

### 14. Others

The description above is intended to be illustrative and the present disclosure is not limited thereto. Therefore, it would be obvious to those skilled in the art that various modifications to the embodiments of the present disclosure would be possible without departing from the spirit and the scope of the appended claims. Further, it would be also obvious for those skilled in the art that embodiments of the present disclosure would be appropriately combined.

The terms used throughout the present specification and the appended claims should be interpreted as non-limiting terms. For example, terms such as “comprise”, “include”, “have”, and “contain” should not be interpreted to be exclusive of other structural elements. Further, indefinite articles “a/an” described in the present specification and the appended claims should be interpreted to mean “at least one” or “one or more.” Further, “at least one of A, B, and C” should be interpreted to mean any of A, B, C, A+B, A+C, B+C, and A+B+C as well as to include combinations of any thereof and any other than A, B, and C.

What is claimed is:

1. A laser apparatus comprising:
a first seed laser configured to output continuous-wave first seed laser light having a first oscillation wavelength;
a second seed laser configured to output continuous-wave second seed laser light having a second oscillation wavelength;
an optical switch configured to sequentially select the first seed laser light and the second seed laser light one at a time and output the selected seed laser light as selected laser light;
a first pulsing section configured to pulse the selected laser light and output first pulse laser light;
a wavelength converter configured to output output laser light by using the first pulse laser light, the wavelength converter outputting the output laser light having a first converted wavelength produced by wavelength conversion using the first oscillation wavelength, the wavelength converter outputting the output laser light having a second converted wavelength produced by wavelength conversion using the second oscillation wavelength; and
a processor configured to control a timing at which the optical switch sequentially selects the first seed laser light and the second seed laser light one at a time.

2. The laser apparatus according to claim 1,
wherein the processor is configured to receive a trigger signal from an external apparatus and controls the optical switch and the first pulsing section with respect to a timing of the reception of the trigger signal.

3. The laser apparatus according to claim 1,
wherein the processor is configured to control the timing at which the optical switch sequentially selects the first seed laser light and the second seed laser light one at a time in such a way that a pulse temporal waveform of each pulse of the first pulse laser light has a portion including the first seed laser light and a portion including the second seed laser light.

4. The laser apparatus according to claim 1,
wherein the processor is configured to adjust a ratio between light intensity of the first seed laser light and light intensity of the second seed laser light in such a way that a wavelength component having the first converted wavelength and a wavelength component having the second converted wavelength out of the output laser light differ from each other in terms of accumulated energy.

5. The laser apparatus according to claim 1,
wherein the processor is configured to control the optical switch in such a way that transmittance of the optical switch achieved when the first seed laser light is selected differs from transmittance of the optical switch achieved when the second seed laser light is selected.

6. The laser apparatus according to claim 1,
wherein the first pulsing section includes a laser crystal configured to amplify the selected laser light, and a pumping laser configured to output pulse-shaped pumping laser light for exciting the laser crystal, and
the processor is configured to control the pumping laser in such a way that pulse energy of the pumping laser light achieved when the optical switch selects the first seed laser light differs from pulse energy of the pumping laser light achieved when the optical switch selects the second seed laser light.

7. The laser apparatus according to claim 1,
further comprising a third seed laser configured to output continuous-wave third seed laser light having a third oscillation wavelength,
wherein the optical switch is configured to sequentially select the first seed laser light, the second seed laser light, and the third seed laser light one at a time, and output the selected seed laser light as the selected laser light,
the wavelength converter is configured to output the output laser light having a third converted wavelength produced by wavelength conversion using the third oscillation wavelength, and
the processor is configured to control a timing at which the optical switch sequentially selects the first seed laser light, the second seed laser light, and the third seed laser light one at a time.

8. The laser apparatus according to claim 1, further comprising:
a fourth seed laser configured to output continuous-wave fourth seed laser light having a fourth oscillation wavelength; and
a second pulsing section configured to pulse the fourth seed laser light and output second pulse laser light;
wherein the wavelength converter is configured to further use the second pulse laser light to perform wavelength conversion using the first and fourth oscillation wavelengths to output the output laser light having the first converted wavelength, and perform wavelength conversion using the second and fourth oscillation wavelengths to output the output laser light having the second converted wavelength.

9. The laser apparatus according to claim 8,
wherein the wavelength converter includes a first nonlinear optical crystal and a beam splitter configured to split the first pulse laser light toward the first nonlinear optical crystal and the second pulsing section, and
the second pulsing section is configured to output the second pulse laser light toward the first nonlinear optical crystal in accordance with a timing of incidence of the first pulse laser light.

10. The laser apparatus according to claim 9,
wherein the wavelength converter further includes a second nonlinear optical crystal disposed in an optical path of the first pulse laser light between the first pulsing section and the beam splitter.

11. The laser apparatus according to claim 10,
wherein the wavelength converter further includes
a third nonlinear optical crystal disposed in the optical path of the first pulse laser light between the beam splitter and the first nonlinear optical crystal, and
a beam combiner configured to cause the first pulse laser light output from the third nonlinear optical crystal and the second pulse laser light output from the second pulsing section to enter the first nonlinear optical crystal.

12. The laser apparatus according to claim 8,
wherein the wavelength converter includes a plurality of nonlinear optical crystals disposed along an optical path of the first pulse laser light, and a drive mechanism configured to be capable of changing an angle of incidence of the first pulse laser light by rotating at least one of the plurality of nonlinear optical crystals, and
the processor is configured to control the drive mechanism in synchronization with the timing at which the optical switch sequentially selects the first seed laser light and the second seed laser light one at a time.

13. The laser apparatus according to claim 8,
wherein the wavelength converter includes a first nonlinear optical crystal and a beam splitter configured to split the second pulse laser light toward the first nonlinear optical crystal and the first pulsing section, and
the first pulsing section is configured to output the first pulse laser light toward the first nonlinear optical crystal in accordance with a timing of incidence of the second pulse laser light.

14. The laser apparatus according to claim 13,
wherein the wavelength converter further includes a second nonlinear optical crystal disposed in an optical path of the second pulse laser light between the second pulsing section and the beam splitter.

15. The laser apparatus according to claim 14,
wherein the wavelength converter further includes
a third nonlinear optical crystal disposed in the optical path of the second pulse laser light between the beam splitter and the first nonlinear optical crystal, and
a beam combiner configured to cause the second pulse laser light output from the third nonlinear optical crystal and the first pulse laser light output from the first pulsing section to enter the first nonlinear optical crystal.

16. A laser apparatus comprising:
a first seed laser configured to output continuous-wave first seed laser light having a first oscillation wavelength;
a second seed laser configured to output continuous-wave second seed laser light having a second oscillation wavelength;
a first pulsing section configured to pulse the first seed laser light and output first pulse laser light;
a third pulsing section configured to pulse the second seed laser light and output third pulse laser light;
an optical switch configured to sequentially select the first pulse laser light and the third pulse laser light one at a time and output the selected pulse laser light as selected laser light;
a wavelength converter configured to output output laser light by using the selected laser light, the wavelength converter outputting the output laser light having a first converted wavelength produced by wavelength conversion using the first oscillation wavelength, the wavelength converter outputting the output laser light having a second converted wavelength produced by wavelength conversion using the second oscillation wavelength; and
a processor configured to control a timing at which the optical switch sequentially selects the first pulse laser light and the third pulse laser light one at a time.

17. The laser apparatus according to claim 16, further comprising:
a fourth seed laser configured to output continuous-wave fourth seed laser light having a fourth oscillation wavelength; and
a second pulsing section configured to pulse the fourth seed laser light and output second pulse laser light,
wherein the wavelength converter is configured to further use the second pulse laser light to perform wavelength conversion using the first and fourth oscillation wavelengths to output the output laser light having the first converted wavelength, and perform wavelength conversion using the second and fourth oscillation wavelengths to output the output laser light having the second converted wavelength.

18. The laser apparatus according to claim 17,
wherein the wavelength converter includes a first nonlinear optical crystal and a beam splitter configured to split the selected laser light toward the first nonlinear optical crystal and the second pulsing section, and
the second pulsing section is configured to output the second pulse laser light toward the first nonlinear optical crystal in accordance with a timing of incidence of the selected laser light.

19. An electronic device manufacturing method comprising:
generating output laser light by using a laser apparatus;
outputting the output laser light to an exposure apparatus; and
exposing a photosensitive substrate to the output laser light in the exposure apparatus to manufacture electronic devices,
the laser apparatus including
a first seed laser configured to output continuous-wave first seed laser light having a first oscillation wavelength,
a second seed laser configured to output continuous-wave second seed laser light having a second oscillation wavelength,
an optical switch configured to sequentially select the first seed laser light and the second seed laser light one at a time and output the selected seed laser light as selected laser light,
a first pulsing section configured to pulse the selected laser light and output first pulse laser light,
a wavelength converter configured to output the output laser light by using the first pulse laser light, the wavelength converter outputting the output laser light having a first converted wavelength produced by wavelength conversion using the first oscillation wavelength, the wavelength converter outputting the output laser light having a second converted wavelength produced by wavelength conversion using the second oscillation wavelength, and
a processor configured to control a timing at which the optical switch sequentially selects the first seed laser light and the second seed laser light one at a time.

20. An electronic device manufacturing method comprising:
generating output laser light by using a laser apparatus;
outputting the output laser light to an exposure apparatus; and
exposing a photosensitive substrate to the output laser light in the exposure apparatus to manufacture electronic devices,
the laser apparatus including
a first seed laser configured to output continuous-wave first seed laser light having a first oscillation wavelength,
a second seed laser configured to output continuous-wave second seed laser light having a second oscillation wavelength,
a first pulsing section configured to pulse the first seed laser light and output first pulse laser light,
a third pulsing section configured to pulse the second seed laser light and output third pulse laser light,
an optical switch configured to sequentially select the first pulse laser light and the third pulse laser light one at a time and output the selected pulse laser light as selected laser light,
a wavelength converter configured to output the output laser light by using the selected laser light, the wavelength converter outputting the output laser light having a first converted wavelength produced by wavelength conversion using the first oscillation wavelength, the wavelength converter outputting the output laser light having a second converted wavelength produced by wavelength conversion using the second oscillation wavelength, and
a processor configured to control a timing at which the optical switch sequentially selects the first pulse laser light and the third pulse laser light one at a time.
